(19) United States
(12) Patent Application Publication
(10) Pub. No.: US 2025/0201717 A1
(43) Pub. Date: Jun. 19, 2025

(54) SEMICONDUCTOR MEMORY DEVICE

(71) Applicant: Kioxia Corporation, Tokyo (JP)

(72) Inventors: Shigehiro WATANABE, Yokkaichi Mie (JP); Megumi ISHIDUKI, Yokkaichi Mie (JP)

(73) Assignee: Kioxia Corporation, Tokyo (JP)

(21) Appl. No.: 18/828,023

(22) Filed: Sep. 9, 2024

(30) Foreign Application Priority Data
Dec. 19, 2023 (JP) 2023-214204

(51) Int. Cl. H01L 23/532; G11C 16/04; H10B 43/10; H10B 43/27

(52) U.S. Cl. CPC H01L 23/53295; G11C 16/0483; H10B 43/10; H10B 43/27

(57) ABSTRACT

A semiconductor memory device includes: conductive layers stacked in a stacking direction and including first conductive layers extending in a first direction over a semiconductor column region, a first terrace region, and a second terrace region, a second conductive layer including a terrace portion provided in the first terrace region, and a third conductive layer including a terrace portion provided in the second terrace region; a semiconductor column disposed in the semiconductor column region; a gate insulating film disposed between the conductive layers and the semiconductor column; and a first insulating member including a first insulating portion extending in the first direction in the first terrace region and a second insulating portion extending in the first direction in the second terrace region. The second insulating portion has a width in a second direction smaller than a width in the second direction of the first insulating portion.

### CROSS-REFERENCE TO RELATED APPLICATIONS

This application is based upon and claims the benefit of Japanese Patent Application No. 2023-214204, filed on Dec. 19, 2023, the entire contents of which are incorporated herein by reference.

### BACKGROUND

### Field

Embodiments described herein relate generally to a semiconductor memory device.

### Description of the Related Art

There has been known a semiconductor memory device including a plurality of conductive layers stacked in a stacking direction, a semiconductor column extending in the stacking direction and opposed to the plurality of conductive layers, and a gate insulating film disposed between the plurality of conductive layers and the semiconductor column. The gate insulating film includes, for example, an electric charge accumulating film of silicon nitride (SiN) or the like.

### BRIEF DESCRIPTION OF THE DRAWINGS

FIG. 1 is a schematic block diagram illustrating a semiconductor memory device according to a first embodiment;

FIG. 2 is a schematic circuit diagram of a memory block BLK;

FIG. 3 is a schematic plan view of a memory die MD;

FIG. 4 is a schematic plan view of a semiconductor column region R_{MH};

FIG. 5 is a schematic cross-sectional view of the semiconductor column region R_{MH};

FIG. 6 is a schematic cross-sectional view of the semiconductor column region R_{MH};

FIG. 7 is a schematic plan view of a hook-up region R_{HUD};

FIG. 8 is a schematic plan view of the hook-up region R_{HUD};

FIG. 9 is a schematic cross-sectional view of the hook-up region R_{HUD};

FIG. 10 is a schematic cross-sectional view of the hook-up region R_{HUD};

FIG. 11 is a schematic cross-sectional view of a hook-up region R_{HUW};

FIG. 12 is a schematic cross-sectional view for describing a method for manufacturing the semiconductor memory device according to the first embodiment;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic plan view for describing the manufacturing method;

FIG. 25 is a schematic cross-sectional view for describing the manufacturing method;

FIG. 26 is a schematic cross-sectional view for describing the manufacturing method;

FIG. 27 is a schematic plan view of a semiconductor memory device according to a second embodiment; and

FIG. 28 is a schematic plan view of a semiconductor memory device according to a third embodiment.

### DETAILED DESCRIPTION

A semiconductor memory device according to one embodiment comprises a plurality of conductive layers stacked in a stacking direction. The plurality of conductive layers include: a plurality of first conductive layers extending in a first direction intersecting with the stacking direction over a semiconductor column region, a first terrace region, and a second terrace region arranged in the first direction; a second conductive layer extending in the first direction over the semiconductor column region and the first terrace region and including a terrace portion provided in the first terrace region; and a third conductive layer disposed between the plurality of first conductive layers and the second conductive layer, extending in the first direction over the semiconductor column region, the first terrace region, and the second terrace region, and including a terrace portion provided in the second terrace region. The semiconductor memory device comprises: a semiconductor column disposed in the semiconductor column region, extending in the stacking direction, and opposed to the plurality of conductive layers; a gate insulating film disposed between the plurality of conductive layers and the semiconductor column and including an electric charge accumulating film; and a first insulating member extending in the stacking direction in a range corresponding to a part of the plurality of conductive layers including the second conductive layer and the third conductive layer in the stacking direction. The first insulating member includes: a first insulating portion extending in the first direction in the first terrace region; and a second insulating portion extending in the first direction in the second terrace region. The second insulating portion has a width in a second direction intersecting with the stacking direction and the first direction at a first position in the stacking direction smaller than a width in the second direction of the first insulating portion at the first position in the stacking direction.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a surface of the substrate is referred to as a stacking direction in some cases. A direction along a predetermined plane intersecting with the stacking direction may be referred to as a first direction, and a direction along the plane and intersecting with the first direction may be referred to as a second direction. The stacking direction may correspond to the Z-direction and need not correspond to the Z-direction. The first direction and the second direction may and need not each correspond to any of the X-direction or the Y-direction.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

### First Embodiment

### [Circuit Configuration]

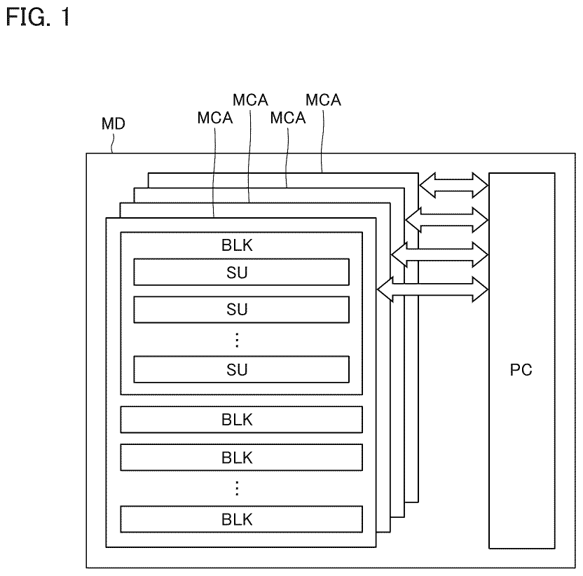

FIG. 1 is a schematic block diagram illustrating a semiconductor memory device according to the first embodiment. The semiconductor memory device according to the embodiment includes a memory die MD. The memory die MD includes a plurality of memory cell arrays MCA and a peripheral circuit PC. Each of the plurality of memory cell arrays MCA includes a plurality of memory blocks BLK. Each of the plurality of memory blocks BLK includes a plurality of string units SU. The peripheral circuit PC includes, for example, a voltage generation circuit that generates an operating voltage, a voltage transfer circuit that transfers the generated operating voltage to respective wirings in a selected memory block BLK, a sense amplifier module connected to a bit line BL, and a sequencer that controls them.

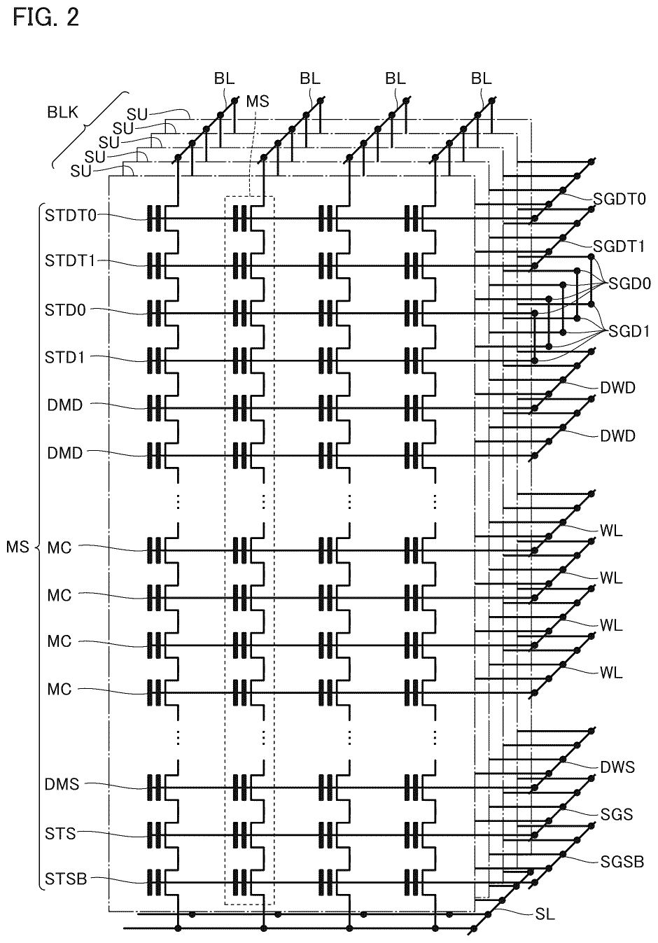

FIG. 2 is a schematic circuit diagram of the memory block BLK. As described above, the memory block BLK includes a plurality of string units SU. Each of these plurality of string units SU includes a plurality of memory strings MS. These plurality of memory strings MS have one ends each connected to the peripheral circuit PC (FIG. 1) via bit lines BL. These plurality of memory strings MS have other ends each connected to the peripheral circuit PC (FIG. 1) via a common source line SL.

The memory string MS includes drain-side select transistors STDT0, STDT1, STD0, STD1, a plurality of dummy memory cells DMD, a plurality of memory cells MC (memory transistors), a plurality of dummy memory cell DMS, and source-side select transistors STS, STSB. The drain-side select transistors STDT0, STDT1, STD0, STD1, the plurality of dummy memory cells DMD, the plurality of memory cells MC, the plurality of dummy memory cells DMS, and the source-side select transistors STS, STSB are connected in series between the bit line BL and the source line SL. Hereinafter, the drain-side select transistors STDT0, STDT1, STD0, STD1, and the source-side select transistors STS, STSB may be simply referred to as select transistors STDT0, STDT1, STD0, STD1, STS, STSB.

The memory cell MC is a field-effect type transistor. The memory cell MC includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores data of 1 bit or a plurality of bits. The gate electrodes of the plurality of memory cells MC corresponding to one memory string MS are connected to respective word lines WL. These respective word lines WL are connected to all of the memory strings MS in one memory block BLK in common.

The dummy memory cells DMD, DMS are basically configured similarly to the memory cell MC. However, the dummy memory cells DMD, DMS do not store data. Respective dummy word lines DWD are connected to gate electrodes of the plurality of dummy memory cells DMD corresponding to one memory string MS. These respective dummy word lines DWD are connected to all of the memory strings MS in one memory block BLK in common. Similarly, a dummy word line DWS is connected to a gate electrode of the dummy memory cell DMS corresponding to one memory string MS. The dummy word line DWS is connected to all of the memory strings MS in one memory block BLK in common.

The select transistors STDT0, STDT1, STD0, STD1, STS, STSB are field-effect type transistors. The select transistors STDT0, STDT1, STD0, STD1, STS, STSB each include a semiconductor layer, a gate insulating film, and a gate electrode. The semiconductor layer functions as a channel region. Select gate lines SGDT0, SGDT1, SGD0, SGD1, SGS, SGSB are connected to the gate electrodes of the select transistors STDT0, STDT1, STD0, STD1, STS, STSB, respectively. Each of the drain-side select gate lines SGDT0, SGDT1 is connected to all the memory strings MS in one memory block BLK in common. Each of the drain-side select gate lines SGD0, SGD1 is connected to all the memory strings MS in one string unit SU in common. The source-side select gate line SGS is connected to all the memory strings MS in one memory block BLK in common. The source-side select gate line SGSB is connected to all the memory strings MS in one memory block BLK in common.

### [Structure]

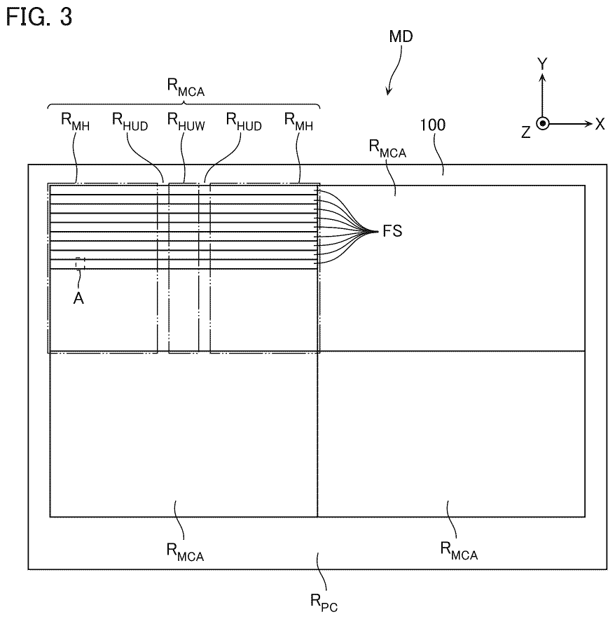

FIG. 3 is a schematic plan view of the memory die MD. The memory die MD includes a semiconductor substrate 100. In the illustrated example, the semiconductor substrate 100 includes four memory cell array regions R_{MCA} arranged in the X-direction and the Y-direction, and a peripheral circuit region R_{PC}. In each of the memory cell array regions R_{MCA}, the above-described memory cell array MCA (FIG. 1) is disposed. In the peripheral circuit region R_{PC}, a part of the above-described peripheral circuit PC (FIG. 1) is disposed.

The memory cell array region R_{M}CA includes a plurality of finger structure FS arranged in the Y-direction. In this embodiment, one finger structure FS functions as one memory block BLK (FIG. 1, FIG. 2). However, a plurality of finger structures FS may function as one memory block BLK.

Each of the memory cell array regions R_{MCA} includes two semiconductor column regions R_{MH} arranged in the X-direction, two hook-up regions R_{HUD} arranged in the X-direction between the two semiconductor column regions R_{MH}, and a hook-up region R_{HU}w disposed between the two hook-up regions R_{HUD}. The following sequentially describes configurations in these regions.

### [Structure in Semiconductor Column Region R_{MH}]

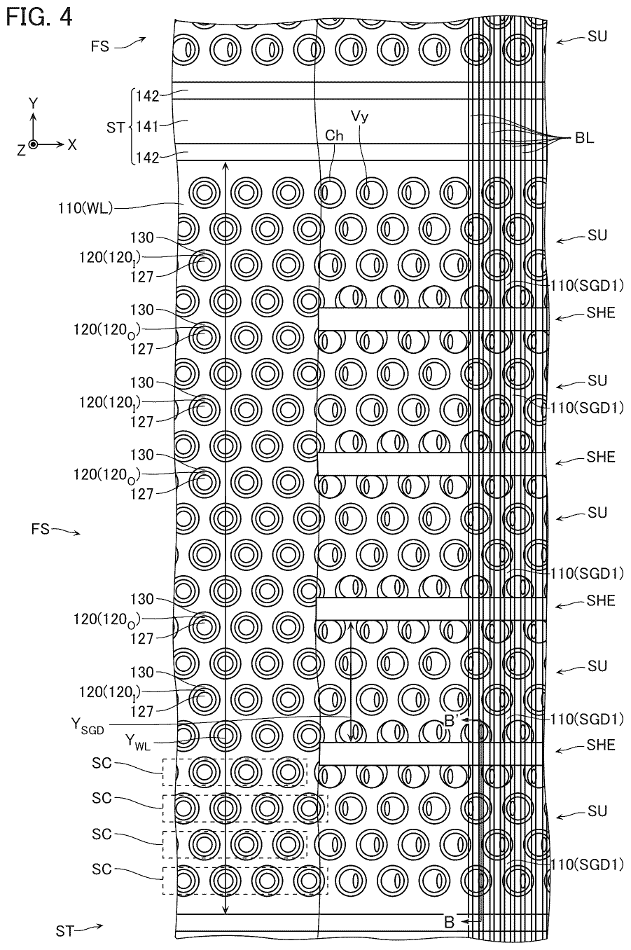

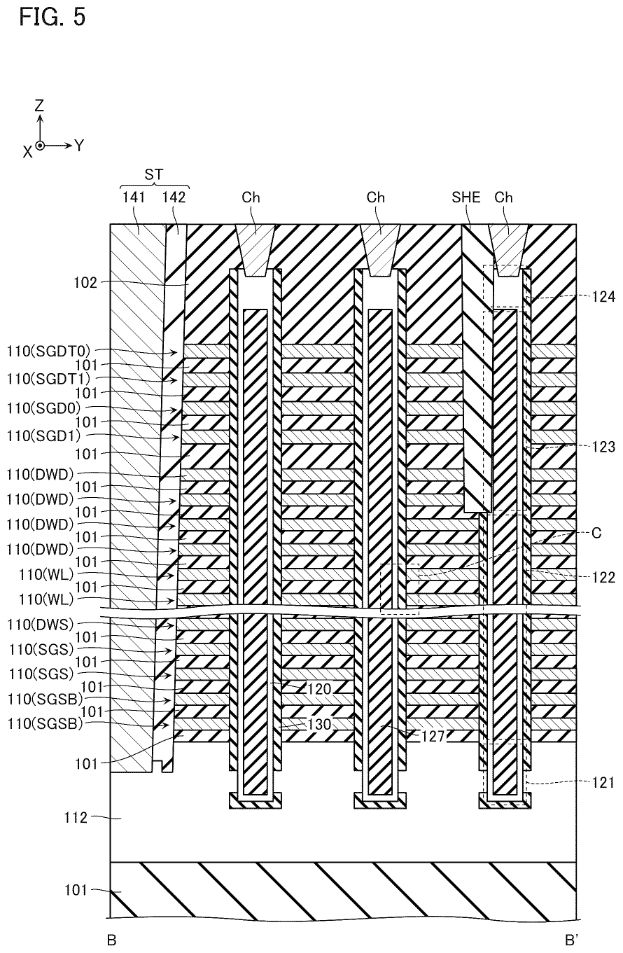

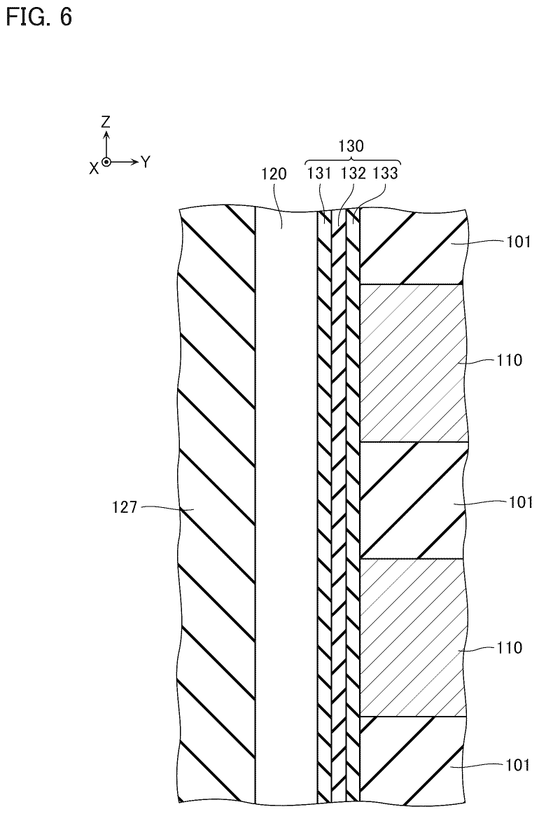

First, with reference to FIG. 4 to FIG. 6, the structure in the semiconductor column region R_{MH} is described. FIG. 4 is a schematic plan view of the semiconductor column region R_{MH}, and illustrates an enlarged part A of FIG. 3. In a part of the region of FIG. 4, an XY cross-sectional surface at a height position corresponding to a conductive layer 110 (WL) described later is illustrated. The remaining region of FIG. 4 illustrates a drawing viewed from above. In this remaining region, an insulating layer 102 and conductive layers 110 (SGDT0), 110 (SGDT1), 110 (SGD0) described later are omitted. In a part of this remaining region, the bit lines BL are omitted. FIG. 5 is a schematic cross-sectional view of the semiconductor column region R_{MH}, and illustrates a cross-sectional surface of the structure of FIG. 4 taken along the line B-B′ and viewed in an arrow direction. FIG. 6 is a schematic cross-sectional view of the semiconductor column region R_{MH}, and illustrates an enlarged part C of FIG. 5. While FIG. 6 indicates a YZ cross-sectional surface, when a cross-sectional surface other than the YZ cross-sectional surface (for example, an XZ cross-sectional surface) along the center axis of a semiconductor column 120 described later is observed, a structure similar to that of FIG. 6 is also observed.

The finger structure FS includes, for example, as illustrated in FIG. 4, five string units SU arranged in the Y-direction. Between two finger structures FS adjacent in the Y-direction, an inter-finger structure ST is disposed. Between two string units SU adjacent in the Y-direction, an inter-string unit insulating member SHE of silicon oxide (SiO₂) or the like is disposed. The finger structure FS may include two to four string units SU, and may include six or more string units SU.

As illustrated in FIG. 5, the finger structure FS includes a plurality of conductive layers 110 arranged in the Z-direction, a conductive layer 112 disposed below these plurality of conductive layers 110, and a plurality of semiconductor columns 120 extending in the Z-direction. Between the plurality of conductive layers 110 and the plurality of semiconductor columns 120, respective gate insulating films 130 are disposed.

The conductive layer 110 has an approximately plate shape extending in the X-direction. The conductive layer 110 may include, for example, a stacked film of a barrier conductive film of titanium nitride (TiN) or the like and a metal film of tungsten (W) or the like. For example, the conductive layer 110 may contain polycrystalline silicon containing impurities, such as phosphorus (P) or boron (B), or the like. Between the plurality of conductive layers 110 arranged in the Z-direction, insulating layers 101 of silicon oxide (SiO₂) or the like are disposed. An insulating layer 102 of, for example, silicon oxide (SiO₂) is disposed on an upper surface of the uppermost conductive layer 110.

A plurality of conductive layers 110 function as the word lines WL (FIG. 2) and gate electrodes of the plurality of memory cells MC (FIG. 2) connected to the word lines WL. In the following description, such conductive layers 110 are referred to as conductive layers 110 (WL) in some cases. The plurality of conductive layers 110 (WL) are each electrically independent for each finger structure FS. Side surfaces in a Y-direction positive side and a Y-direction negative side of the conductive layer 110 (WL) are electrically insulated from configurations in another finger structure FS via the inter-finger structure ST.

One or a plurality of conductive layers 110 positioned below the plurality of conductive layers 110 (WL) function as the dummy word lines DWS (FIG. 2) and gate electrodes of the plurality of dummy memory cells DMS (FIG. 2) connected to the dummy word lines DWS. In the following description, such conductive layers 110 are referred to as conductive layers 110 (DWS) in some cases. The conductive layer 110 (DWS) is configured similarly to the conductive layer 110 (WL).

One or a plurality of conductive layers 110 positioned below the plurality of conductive layers 110 (DWS) function as the source-side select gate lines SGS (FIG. 2) and gate electrodes of the plurality of source-side select transistors STS (FIG. 2) connected to the source-side select gate lines SGS. In the following description, such conductive layers 110 are referred to as conductive layers 110 (SGS) in some cases. The conductive layer 110 (SGS) is configured similarly to the conductive layer 110 (WL).

One or a plurality of conductive layers 110 positioned below the plurality of conductive layers 110 (SGS) function as the source-side select gate lines SGSB (FIG. 2) and gate electrodes of the plurality of source-side select transistors STSB (FIG. 2) connected to the source-side select gate lines SGSB. In the following description, such conductive layers 110 are referred to as conductive layers 110 (SGSB) in some cases. The conductive layer 110 (SGSB) is configured similarly to the conductive layer 110 (WL).

One or a plurality of conductive layers 110 positioned above the plurality of conductive layers 110 (WL) function as the dummy word lines DWD (FIG. 2) and gate electrodes of the plurality of dummy memory cells DMD (FIG. 2) connected to the dummy word lines DWD. In the following description, such conductive layers 110 are referred to as conductive layers 110 (DWD) in some cases. A part of the conductive layers 110 (DWD) may be configured similarly to the conductive layer 110 (WL). The other part of the conductive layers 110 (DWD) disposed above these part of conductive layers 110 (DWD) may be basically configured similarly to a conductive layer 110 (SGD1) described later. However, five conductive layers 110 (DWD) arranged in the Y-direction at a predetermined height position in one finger structure FS are mutually electrically connected.

One conductive layer 110 positioned above the one or the plurality of conductive layers 110 (DWD) functions as the drain-side select gate line SGD1 (FIG. 2) and gate electrodes of the plurality of drain-side select transistors STD1 (FIG. 2) connected to the drain-side select gate line SGD1. In the following description, such a conductive layer 110 is referred to as a conductive layer 110 (SGD1) in some cases.

As illustrated in FIG. 4, the finger structure FS includes five conductive layers 110 (SGD1) arranged in the Y-direction at a predetermined height position via the inter-string unit insulating members SHE. The conductive layer 110 (SGD1) has a width Y_{SGD} in the Y-direction smaller than a width Y_{WL} in the Y-direction of the conductive layer 110 (WL). These five conductive layers 110 (SGD1) are each electrically independent for each string unit SU. The conductive layers 110 (SGD1) corresponding to first and fifth string units SU counted from one side in the Y-direction (for example, negative side in the Y-direction) in each finger structure FS are electrically insulated from the configurations of other finger structures FS via the inter-finger structures ST disposed between the finger structures FS. In each finger structure FS, two conductive layers 110 (SGD1) adjacent in the Y-direction are electrically insulated via the inter-string unit insulating member SHE.

One conductive layer 110 positioned above the conductive layer 110 (SGD1) functions as the drain-side select gate line SGD0 (FIG. 2) and gate electrodes of the plurality of drain-side select transistors STD0 (FIG. 2) connected to the drain-side select gate line SGD0. In the following description, such a conductive layer 110 is referred to as a conductive layer 110 (SGD0) in some cases. The conductive layer 110 (SGD0) is configured similarly to the conductive layer 110 (SGD1). Five conductive layers 110 (SGD0) arranged in the Y-direction at a predetermined height position in one finger structure FS are each electrically independent for each string unit SU.

One conductive layer 110 positioned above the conductive layer 110 (SGD0) functions as the drain-side select gate line SGDT1 (FIG. 2) and gate electrodes of the plurality of drain-side select transistors STDT1 (FIG. 2) connected to the drain-side select gate line SGDT1. In the following description, such a conductive layer 110 is referred to as a conductive layer 110 (SGDT1) in some cases. The conductive layer 110 (SGDT1) is basically configured similarly to the conductive layer 110 (SGD1). However, five conductive layers 110 (SGDT1) arranged in the Y-direction at a predetermined height position in one finger structure FS are mutually electrically connected.

One conductive layer 110 positioned above the conductive layer 110 (SGDT1) functions as the drain-side select gate line SGDT0 (FIG. 2) and gate electrodes of the plurality of drain-side select transistors STDT0 (FIG. 2) connected to the drain-side select gate line SGDT0. In the following description, such a conductive layer 110 is referred to as a conductive layer 110 (SGDT0) in some cases. The conductive layer 110 (SGDT0) is configured similarly to the conductive layer 110 (SGDT1). Five conductive layers 110 (SGDT0) arranged in the Y-direction at a predetermined height position in one finger structure FS are mutually electrically connected.

The conductive layer 112 (FIG. 5) may contain, for example, polycrystalline silicon containing impurities, such as phosphorus (P) or boron (B). At a lower surface of the conductive layer 112, for example, a conductive layer of a metal, such as tungsten (W), tungsten silicide, or the like, or another conductive layer may be disposed. Between the conductive layer 112 and the conductive layer 110, an insulating layer 101 of silicon oxide (SiO₂) or the like is disposed.

The conductive layer 112 functions as a part of the source line SL (FIG. 2). The conductive layer 112 is, for example, disposed in common to all the finger structures FS included in the memory cell array region R_{MCA} (FIG. 3).

The semiconductor columns 120 are, for example, as illustrated in FIG. 4, arranged in the X-direction and the Y-direction in a predetermined pattern. For example, the finger structure FS includes 20 semiconductor column rows SC disposed from one side in the Y-direction to the other side in the Y-direction. Each of these 20 semiconductor column rows SC includes the plurality of semiconductor columns 120 arranged in the X-direction.

Hereinafter, semiconductor columns 120 corresponding to 4n-th (n is an integer of 1 or more and 4 or less) and 4n+1-th semiconductor column rows SC counted from one side in the Y-direction are referred to as a semiconductor column 120ₒ in some cases. The semiconductor columns 120 corresponding to 1st, 2nd, 3rd, 4n+2-th, 4n+3-th, and 20th semiconductor column rows SC counted from one side in the Y-direction are referred to as a semiconductor column 120_{I} in some cases.

The semiconductor column 120 contains, for example, polycrystalline silicon (Si). As illustrated in FIG. 5, for example, the semiconductor column 120 has an approximately cylindrical shape, and its center part is provided with an insulating column 127 of silicon oxide (SiO₂) or the like.

The semiconductor column 120 includes a region 121 disposed below a lower surface of the lowermost conductive layer 110, a region 122 disposed above the region 121 and disposed below a lower end of the inter-string unit insulating member SHE, a region 123 disposed above the region 122 and disposed below an upper end of the insulating column 127, and a region 124 disposed above the region 123.

The region 121 contains N-type impurities, such as phosphorus (P). The region 121 has an approximately cylindrical shape. The region 121 is connected to the conductive layer 112.

The region 122 is opposed to the plurality of conductive layers 110 (SGSB), 110 (SGS), 110 (DWS), 110 (WL). The region 122 may be opposed to at least a part of the plurality of conductive layers 110 (DWD). The region 122 functions as channel regions of the memory cell MC (FIG. 2), the dummy memory cell DMS (FIG. 2), and the select transistors STS, STSB (FIG. 2). The region 122 may function as channel regions of at least a part of the dummy memory cells DMD (FIG. 2). The region 122 need not contain N-type impurities, such as phosphorus (P). The region 122 has an approximately cylindrical shape.

The region 123 is opposed to the conductive layers 110 (SGD1), 110 (SGD0), 110 (SGDT1), 110 (SGDT0). The region 123 may be opposed to at least a part of the plurality of conductive layers 110 (DWD). The region 123 functions as channel regions of the select transistors STDT0, STDT1, STD0, STD1 (FIG. 2). The region 123 may function as channel regions of at least a part of the dummy memory cells DMD. The region 123 need not contain N-type impurities, such as phosphorus (P).

The region 123 of the semiconductor column 120_{I} has an approximately cylindrical shape. On the other hand, the region 123 of the semiconductor column 120ₒ has a shape in which a part of cylinder is missing (arc-like shape in an XY cross-sectional surface).

The region 124 contains N-type impurities, such as phosphorus (P). The region 124 is electrically connected to bit lines BL extending in the Y-direction via a via-contact electrode Ch and a via-contact electrode Vy (FIG. 4) extending in the Z-direction. The via-contact electrode Ch and the via-contact electrode Vy may include, for example, a stacked film of a barrier conductive film of titanium nitride (TiN) or the like and a metal film of tungsten (W) or the like. The bit line BL may include, for example, a stacked film of a barrier conductive film of titanium nitride (TiN) or the like and a metal film of copper (Cu) or the like.

The region 124 of the semiconductor column 120_{I} has an approximately columnar shape. On the other hand, the region 124 of the semiconductor column 120ₒ has a shape in which apart of column is missing.

The gate insulating film 130 includes, for example, as illustrated in FIG. 6, a tunnel insulating film 131, an electric charge accumulating film 132, and a block insulating film 133, which are stacked between the semiconductor column 120 and the conductive layers 110. The tunnel insulating film 131 and the block insulating film 133 contain, for example, silicon oxide (SiO₂). The electric charge accumulating film 132 is, for example, a film of silicon nitride (SiN) or the like capable of accumulating electric charge.

In the gate insulating film 130, a part disposed at a position corresponding to the region 121 of the semiconductor column 120 has an approximately cylindrical shape and extends in the Z-direction along an outer peripheral surface of the semiconductor column 120 excluding a contact portion between the semiconductor column 120 and the conductive layer 112.

In the gate insulating film 130, a part disposed at a position corresponding to the region 122 of the semiconductor column 120 has an approximately cylindrical shape and extends in the Z-direction along the outer peripheral surface of the semiconductor column 120.

In the gate insulating film 130, a part disposed at a position corresponding to the regions 123, 124 of the semiconductor column 120_{I} has an approximately cylindrical shape and extends in the Z-direction along an outer peripheral surface of the semiconductor column 1201.

In the gate insulating film 130, a part disposed at a position corresponding to the regions 123, 124 of the semiconductor column 120ₒ has a shape in which a part of cylinder is missing (arc-like shape in an XY cross-sectional surface).

As illustrated in FIG. 4 and FIG. 5, for example, the inter-finger structure ST includes an inter-finger electrode 141 extending in the X-direction and the Z-direction, and inter-finger insulating members 142 of silicon oxide (SiO₂) or the like disposed at side surfaces in the Y-direction of the inter-finger electrode 141. A lower end of the inter-finger electrode 141 is connected to the conductive layer 112. Also, an upper end of the inter-finger electrode 141 is positioned above the upper surface of the conductive layer 110 positioned in the uppermost layer. The inter-finger electrode 141 may include, for example, a stacked film of a barrier conductive film of titanium nitride (TiN) or the like and a metal film of tungsten (W) or the like. Also, the inter-finger electrode 141 may contain, for example, polycrystalline silicon containing impurities, such as phosphorus (P) or boron (B). The inter-finger electrode 141 functions as, for example, a part of the source line SL (FIG. 2).

The inter-string unit insulating member SHE contains, for example, silicon oxide (SiO₂). As illustrated in FIG. 4, for example, the inter-string unit insulating member SHE is disposed between every 4n-th semiconductor column row SC and 4n+1-th semiconductor column row SC counted from one side in the Y-direction, and extends in the X-direction. Respective side surfaces of the inter-string unit insulating member SHE in the Y-direction are in contact with either one of the gate insulating films 130 corresponding to the 4n-th semiconductor column row SC and the gate insulating films 130 corresponding to the 4n+1-th semiconductor column row SC counted from one side in the Y-direction, and are spaced from the other.

As illustrated in FIG. 5, the inter-string unit insulating member SHE extends in the Z-direction within a height range corresponding to the insulating layer 102, the conductive layers 110 (SGDT0), 110 (SGDT1), 110 (SGD0), 110 (SGD1), a part of the conductive layers 110 (DWD), and the insulating layers 101 disposed on upper and lower surfaces of these conductive layers 110, and separates these configurations in the Y-direction. A lower end of the inter-string unit insulating member SHE is positioned between a lower surface of the conductive layer 110 (SGD1) and a lower surface of the uppermost conductive layer 110 (WL).

In the illustrated example, viewed in the Z-direction, the inter-string unit insulating member SHE is disposed at a position overlapping with a part of the semiconductor column 1200, and a part of the tunnel insulating film 131, electric charge accumulating film 132, and block insulating film 133, which are disposed between the semiconductor column 120ₒ and the conductive layers 110 and constitute the gate insulating film 130.

### [Structure in Hook-Up Region R_{HUD}]

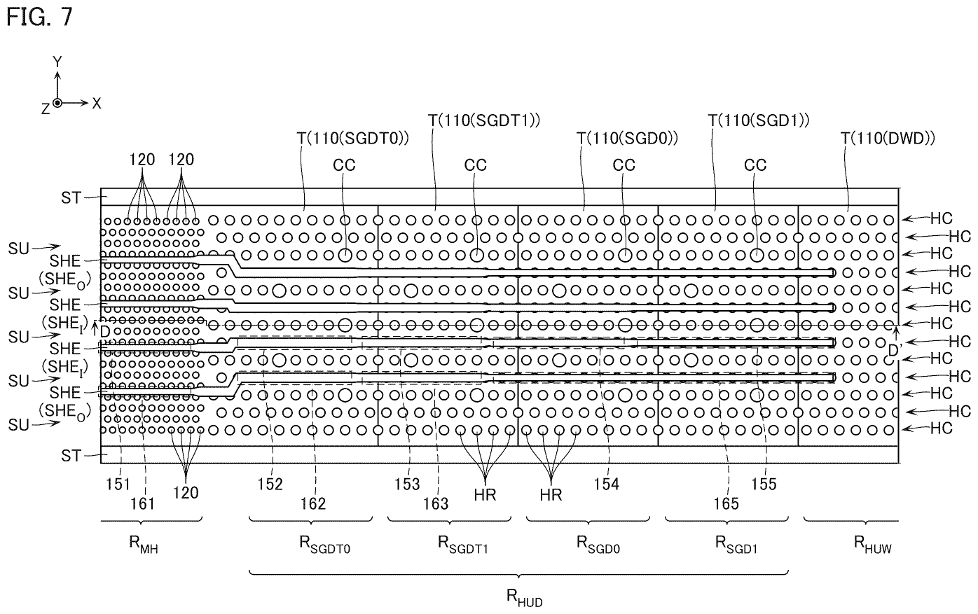

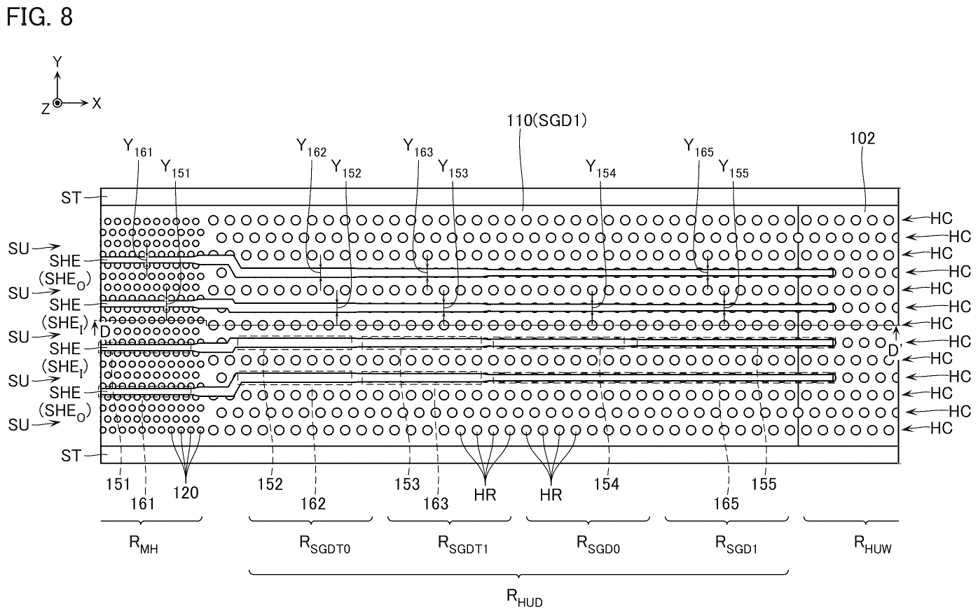

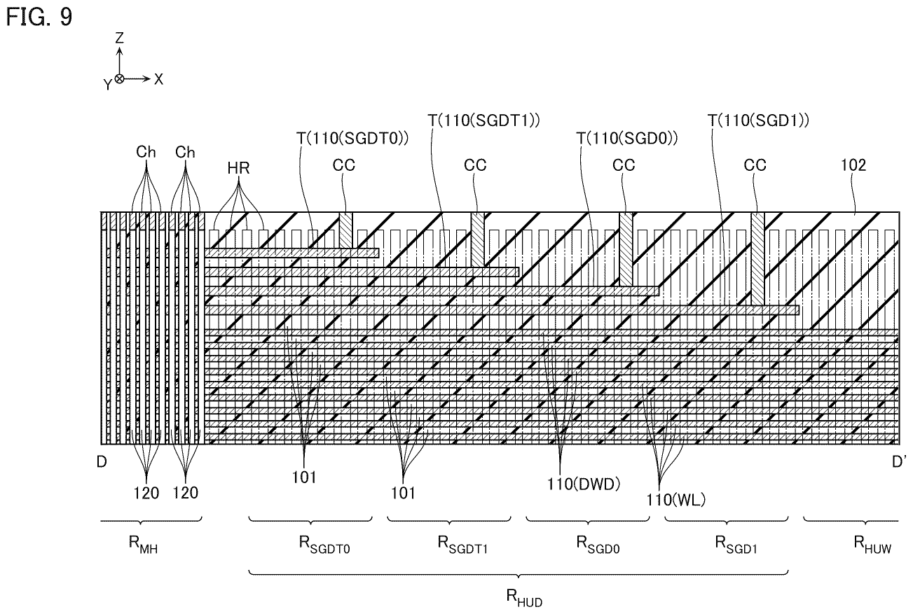

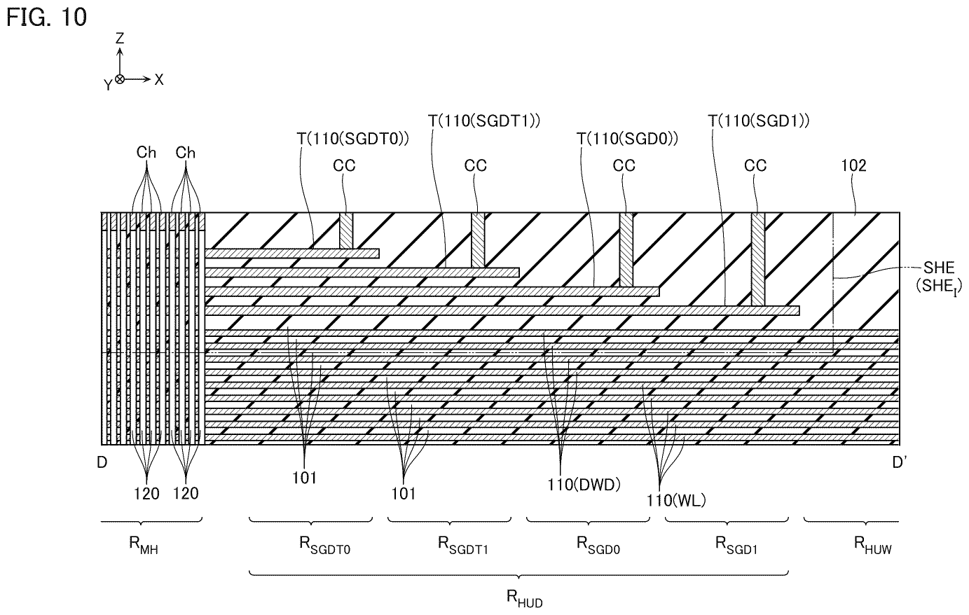

Next, with reference to FIG. 7 to FIG. 10, the structure in the hook-up region R_{HUD} is described. FIG. 7 and FIG. 8 are schematic plan views of the hook-up region R_{HUD}. In FIG. 7, the insulating layer 102 and the bit line BL are omitted. FIG. 8 illustrates an XY cross-sectional surface at a height position corresponding to the conductive layer 110 (SGD1). FIG. 9 and FIG. 10 are schematic cross-sectional views of the hook-up region R_{HUD}, and illustrate cross-sectional surfaces of the structures illustrated in FIG. 7 and FIG. 8 taken along the line D-D′ and viewed along the arrow direction. In FIG. 9, for convenience of illustration, support insulating columns HR described later are indicated by two-dot chain lines. In FIG. 10, for convenience of illustration, the support insulating columns HR described later are omitted, and the inter-string unit insulating member SHE is indicated by the two-dot chain line.

The hook-up region R_{HUD} includes, as illustrated in FIG. 7, terrace regions R_{SGDT0}, R_{SGDT1}, R_{SGD0}, R_{SGD1} sequentially arranged in the X-direction from a semiconductor column region R_{MH} side to a hook-up region R_{HUW} side.

The terrace region R_{SGDT0} includes five terrace portions T of five conductive layers 110 (SGDT0) arranged in the Y-direction at a predetermined height position in one finger structure FS. For example, the terrace portions T are portions of the upper surfaces of the conductive layers 110 not overlapping with other conductive layers 110 viewed from above. As illustrated in FIG. 9, the terrace portions T are covered with the insulating layer 102. The terrace portion T of the conductive layer 110 (SGDT0) is provided at an end portion at the hook-up region R_{HUW} side in the X-direction of the conductive layer 110 (SGDT0).

The terrace region R_{SGDT1} includes five terrace portions T of five conductive layers 110 (SGDT1) arranged in the Y-direction at a predetermined height position in one finger structure FS. The terrace portion T of the conductive layer 110 (SGDT1) is provided at an end portion at the hook-up region R_{HUW} side in the X-direction of the conductive layer 110 (SGDT1).

The terrace region R_{SGD0} includes five terrace portions T of five conductive layers 110 (SGD0) arranged in the Y-direction at a predetermined height position in one finger structure FS. The terrace portion T of the conductive layer 110 (SGD0) is provided at an end portion at the hook-up region R_{HUW} side in the X-direction of the conductive layer 110 (SGD0).

The terrace region R_{SGD1} includes five terrace portions T of five conductive layers 110 (SGD1) arranged in the Y-direction at a predetermined height position in one finger structure FS. The terrace portion T of the conductive layer 110 (SGD1) is provided at an end portion at the hook-up region R_{HUW} side in the X-direction of the conductive layer 110 (SGD1).

As illustrated in FIG. 9, the terrace region R_{SGDT0} includes the conductive layers 110 (SGDT0), 110 (SGDT1), 110 (SGD0), 110 (SGD1).

The terrace region R_{SGDT1} includes the conductive layers 110 (SGDT1), 110 (SGD0), 110 (SGD1), but does not include the conductive layer 110 (SGDT0). Therefore, the number of the conductive layers 110 arranged in the Z-direction in the terrace region R_{SGDT1} is smaller than the number of the conductive layers 110 arranged in the Z-direction in the terrace region R_{SGDT0}.

The terrace region R_{SGD0} includes the conductive layers 110 (SGD0), 110 (SGD1), but does not include the conductive layers 110 (SGDT0), 110 (SGDT1). Therefore, the number of the conductive layers 110 arranged in the Z-direction in the terrace region R_{SGD0} is smaller than the number of the conductive layers 110 arranged in the Z-direction in the terrace region R_{SGDT1}.

The terrace region R_{SGD1} includes the conductive layer 110 (SGD1), but does not include the conductive layers 110 (SGDT0), 110 (SGDT1), 110 (SGD0). Therefore, the number of the conductive layers 110 arranged in the Z-direction in the terrace region R_{SGD1} is smaller than the number of the conductive layers 110 arranged in the Z-direction in the terrace region R_{SGD0}.

The hook-up region R_{HUD} includes a plurality of support insulating columns HR. The support insulating column HR may, for example, contain silicon oxide (SiO₂), or may include a configuration corresponding to the semiconductor column 120, the insulating column 127, and the gate insulating film 130. As illustrated in FIG. 9, the support insulating column HR penetrates a part of the insulating layer 102, a plurality of the conductive layers 110, and a plurality of the insulating layers 101, and extends in the Z-direction. The support insulating columns HR have outer peripheral surfaces each surrounded by a through hole provided at the conductive layers 110.

For example, as illustrated in FIG. 7, the support insulating columns HR are arranged in the X-direction and the Y-direction in a predetermined pattern. For example, the finger structure FS includes 13 support insulating column rows HC provided from one side in the Y-direction to the other side in the Y-direction. Each of these 13 support insulating column rows HC includes a plurality of support insulating columns HR arranged in the X-direction.

The hook-up region R_{HUD} includes a plurality of via-contact electrodes CC corresponding to the plurality of terrace portions T. The via-contact electrode CC may include, for example, a stacked film of a barrier conductive film of titanium nitride (TiN) or the like and a metal film of tungsten (W) or the like. As illustrated in FIG. 9, the via-contact electrode CC penetrates the insulating layer 102 and extends in the Z-direction, and has a lower end connected to the terrace portion T of the conductive layer 110. In the example of FIG. 7, 20 via-contact electrodes CC are disposed correspondingly to the 20 terrace portions T provided in the hook-up region R_{HUD}.

In the example of FIG. 7, respective four via-contact electrodes CC connected to the terrace portions T of the conductive layers 110 (SGDT0), 110 (SGDT1), 110 (SGD0), 110 (SGD1) corresponding to a first string unit SU counted from the Y-direction positive side are provided at positions corresponding to a third support insulating column row HC counted from the Y-direction positive side.

Respective four via-contact electrodes CC connected to the terrace portions T of the conductive layers 110 (SGDT0), 110 (SGDT1), 110 (SGD0), 110 (SGD1) corresponding to a second string unit SU counted from the Y-direction positive side are provided at positions corresponding to a fifth support insulating column row HC counted from the Y-direction positive side.

Respective four via-contact electrodes CC connected to the terrace portions T of the conductive layers 110 (SGDT0), 110 (SGDT1), 110 (SGD0), 110 (SGD1) corresponding to a third string unit SU counted from the Y-direction positive side are provided at positions corresponding to a seventh support insulating column row HC counted from the Y-direction positive side.

Respective four via-contact electrodes CC connected to the terrace portions T of the conductive layers 110 (SGDT0), 110 (SGDT1), 110 (SGD0), 110 (SGD1) corresponding to a fourth string unit SU counted from the Y-direction positive side are provided at positions corresponding to a ninth support insulating column row HC counted from the Y-direction positive side.

Respective four via-contact electrodes CC connected to the terrace portions T of the conductive layers 110 (SGDT0), 110 (SGDT1), 110 (SGD0), 110 (SGD1) corresponding to a fifth string unit SU counted from the Y-direction positive side are provided at positions corresponding to an eleventh support insulating column row HC counted from the Y-direction positive side.

The hook-up region R_{HUD} includes a part of the inter-string unit insulating member SHE. The inter-string unit insulating member SHE extends in the X-direction over the semiconductor column region R_{MH} and hook-up region R_{HUD}, and an end portion in the X-direction of the inter-string unit insulating member SHE reaches a part of the hook-up region R_{HUW}. As illustrated in FIG. 10, the lower end of the inter-string unit insulating member SHE is positioned between the lower surface of the conductive layer 110 (SGD1) and the lower surface of the uppermost conductive layer 110 (WL) also in the hook-up region R_{HUD}. Accordingly, the conductive layers 110 (SGDT0), 110 (SGDT1), 110 (SGD0), 110 (SGD1) are separated in the Y-direction.

In the example of FIG. 7, a first inter-string unit insulating member SHE counted from the Y-direction positive side is provided at a position corresponding to a fourth support insulating column row HC counted from the Y-direction positive side in the hook-up region R_{HUD}.

A second inter-string unit insulating member SHE counted from the Y-direction positive side is provided at a position corresponding to a sixth support insulating column row HC counted from the Y-direction positive side in the hook-up region R_{HUD}.

A third inter-string unit insulating member SHE counted from the Y-direction positive side is provided at a position corresponding to an eighth support insulating column row HC counted from the Y-direction positive side in the hook-up region R_{HUD}.

A fourth inter-string unit insulating member SHE counted from the Y-direction positive side is provided at a position corresponding to a tenth support insulating column row HC counted from the Y-direction positive side in the hook-up region R_{HUD}. In the following description, the first and fourth inter-string unit insulating members SHE counted from the Y-direction positive side are referred to as an inter-string unit insulating member SHEₒ in some cases. The second and third inter-string unit insulating members SHE counted from the Y-direction positive side are referred to as an inter-string unit insulating member SHE_{I} in some cases.

The inter-string unit insulating member SHE_{I} according to the embodiment includes an insulating portion 151 provided in the semiconductor column region R_{MH}, an insulating portion 152 provided in the terrace region R_{SGDT0}, an insulating portion 153 provided in the terrace region R_{SGDT1}, an insulating portion 154 provided in the terrace region R_{SGD0}, and an insulating portion 155 provided in the terrace region R_{SGD1}. Each of the insulating portions 151, 152, 153, 154, 155 has an approximately constant width in the Y-direction and extends in the X-direction. In the example of the drawing, center positions in the Y-direction of the insulating portions 152, 153, 154, 155 are approximately matched. Meanwhile, a center position in the Y-direction of the insulating portion 151 is different from the center positions in the Y-direction of the insulating portions 152, 153, 154, 155. The insulating portion 152 has one end portion and the other end portion in the X-direction provided in the terrace region R_{SGDT0}. The insulating portion 153 has one end portion in the X-direction provided in the terrace region R_{SGDT0}, and the other end portion in the X-direction provided in the terrace region R_{SGDT1}. The insulating portion 154 has one end portion in the X-direction provided in the terrace region R_{SGDT1}, and the other end portion in the X-direction provided in the terrace region R_{SGD0}. The insulating portion 155 has one end portion in the X-direction provided in the terrace region R_{SGD0}, and the other end portion in the X-direction provided in the hook-up region R_{HUW}.

The inter-string unit insulating member SHEₒ according to the embodiment includes an insulating portion 161 provided in the semiconductor column region R_{MH}, an insulating portion 162 provided in the terrace region R_{SGDT0}, an insulating portion 163 provided in the terrace region R_{SGDT1}, and an insulating portion 165 provided in the terrace regions R_{SGD0}, R_{SGD1}. Each of the insulating portions 161, 162, 163, 165 has an approximately constant width in the Y-direction and extends in the X-direction. In the example of the drawing, center positions in the Y-direction of the insulating portions 162, 163, 165 are approximately matched. Meanwhile, a center position in the Y-direction of the insulating portion 161 is different from the center positions in the Y-direction of the insulating portions 162, 163, 165. The insulating portion 162 has one end portion and the other end portion in the X-direction provided in the terrace region R_{SGDT0}. The insulating portion 163 has one end portion in the X-direction provided in the terrace region R_{SGDT0}, and the other end portion in the X-direction provided in the terrace region R_{SGDT1}. The insulating portion 165 has one end portion in the X-direction provided in the terrace region R_{SGDT1}, and the other end portion in the X-direction provided in the hook-up region R_{HUW}.

Here, as illustrated in FIG. 8, widths in the Y-direction Y₁₅₁, Y₁₆₁ of the insulating portions 151, 161 at a height position corresponding to the conductive layer 110 (SGD1) are approximately matched. Widths Y₁₅₂, Y₁₆₂ in the Y-direction of the insulating portions 152, 162 at the above-described height position are approximately matched. The widths Y₁₅₂, Y₁₆₂ are larger than the widths Y₁₅₁, Y₁₆₁. A width Y₁₅₃ in the Y-direction of the insulating portion 153 at the above-described height position is larger than a width Y₁₆₃ in the Y-direction of the insulating portion 163 at the above-described height position. The widths Y₁₅₃, Y₁₆₃ are larger than the widths Y₁₅₁, Y₁₆₁, and smaller than the widths Y₁₅₂, Y₁₆₂. A width Y₁₅₄ in the Y-direction of the insulating portion 154 at the above-described height position is larger than the widths Y₁₅₁, Y₁₆₁, and smaller than the widths Y₁₅₃, Y₁₆₃. Widths Y₁₅₅, Y₁₆₅ in the Y-direction of the insulating portions 155, 165 at the above-described height position are approximately matched with the widths Y₁₅₁, Y₁₆₁.

At the above-described height position, widths of the inter-string unit insulating members SHE_{I}, SHEₒ in the Y-direction each monotonously decrease from the semiconductor column region R_{MH} side to the hook-up region R_{HUW} side in the hook-up region R_{HUD}.

### [Structure of Hook-Up Region R_{HUW}]

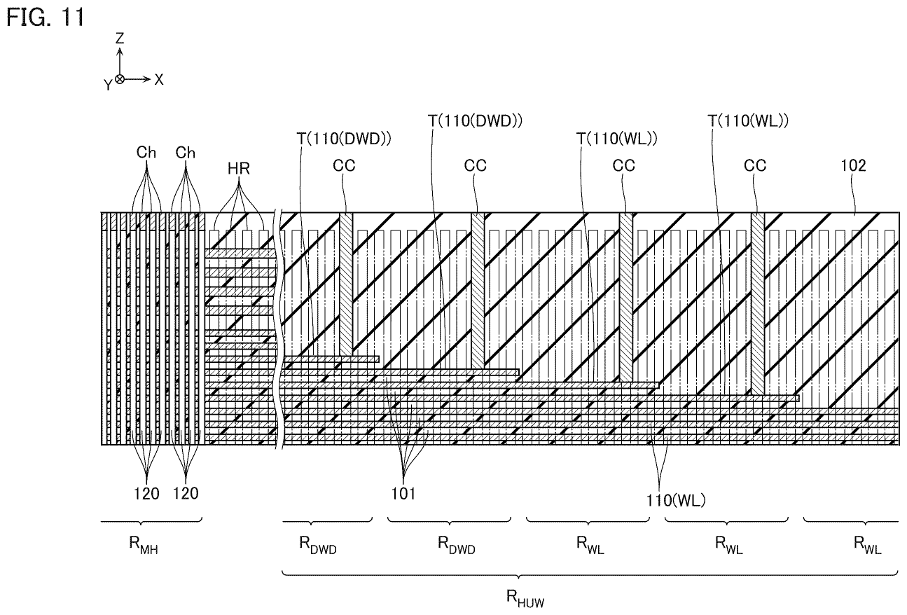

Next, the structure of the hook-up region R_{HUW} is described with reference to FIG. 11. FIG. 11 is a schematic cross-sectional view of the hook-up region R_{HUW}. In FIG. 11, for convenience of illustration, the support insulating columns HR are indicated by two-dot chain lines.

The hook-up region R_{HUW} includes a plurality of terrace regions R_{DWD} and a plurality of terrace regions R_{WL} arranged in the X-direction. Each of the plurality of terrace regions R_{DWD} includes the terrace portion T of the conductive layer 110 (DWD). Each of the plurality of terrace regions R_{WL} includes the terrace portion T of the conductive layer 110 (WL).

Although not illustrated, the hook-up region R_{HUW} includes the terrace portions T of the conductive layers 110 (DWS), 110 (SGS), 110 (SGSB) and terrace regions corresponding to these terrace portions T.

The hook-up region R_{HUW} includes, similarly to the hook-up region R_{HUD}, a plurality of support insulating columns HR and a plurality of via-contact electrodes CC.

### [Manufacturing Method]

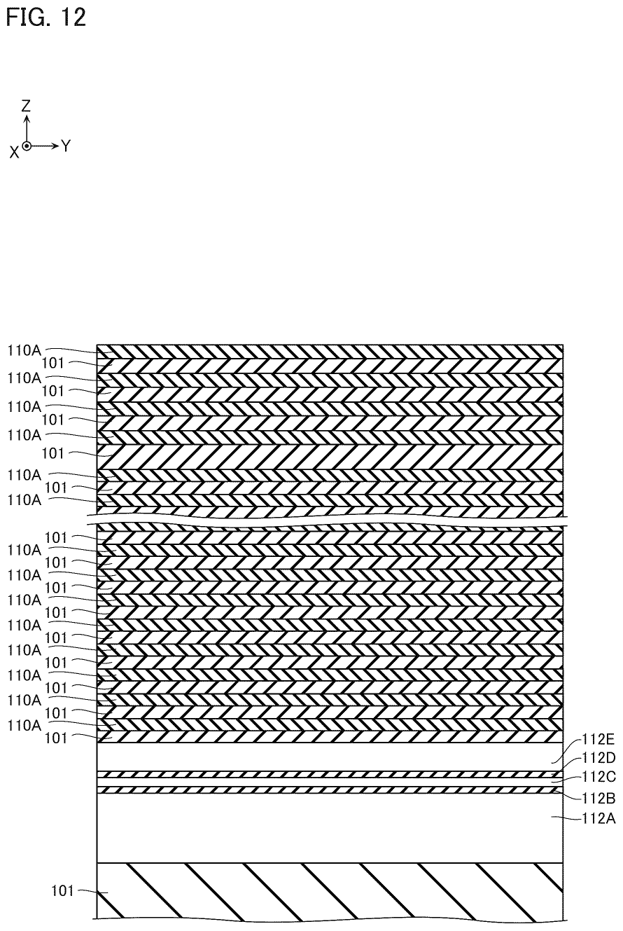

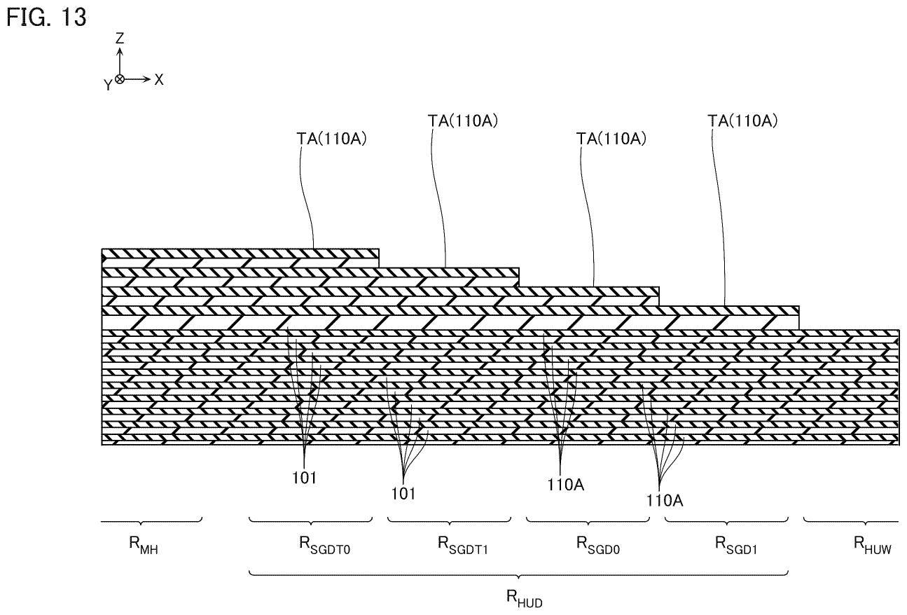

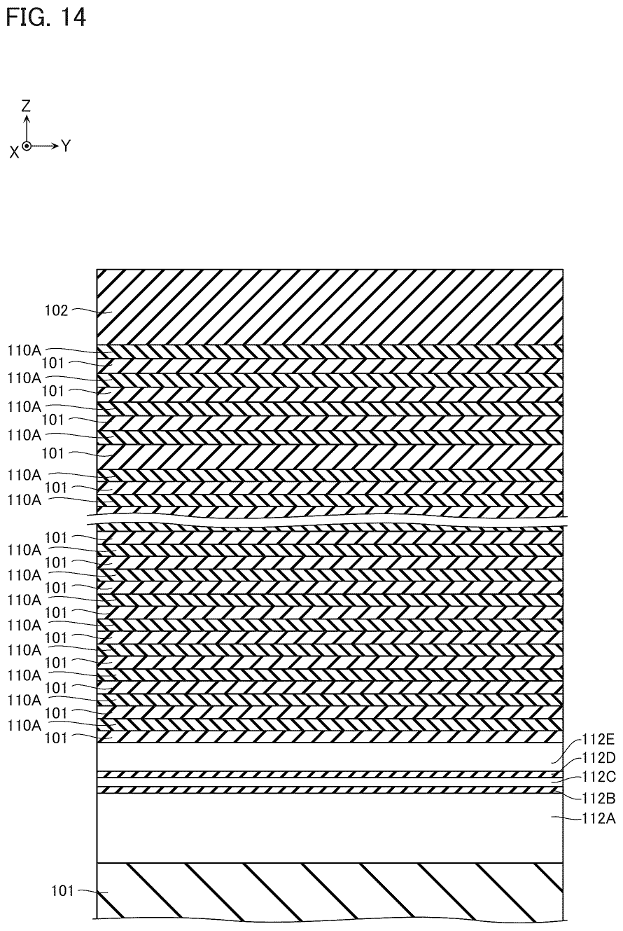

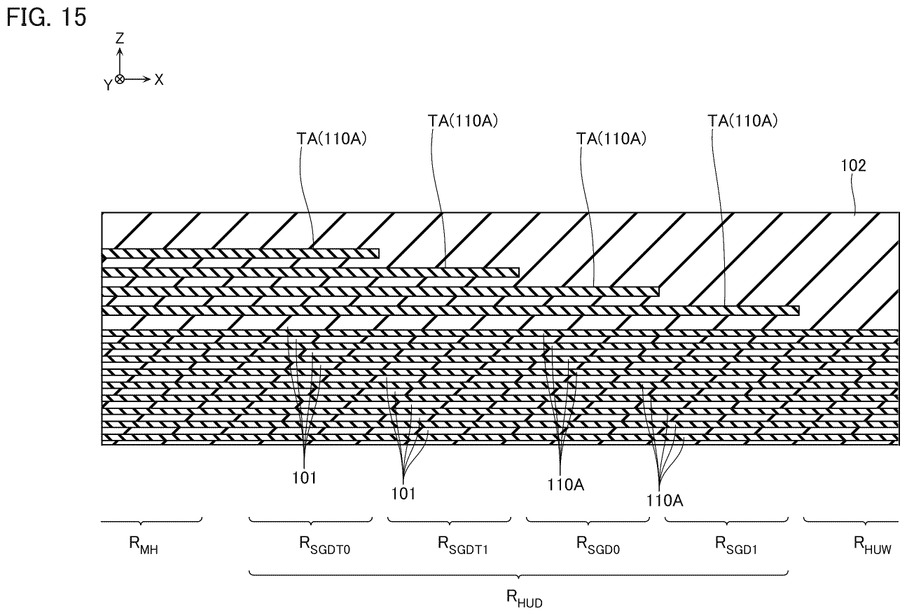

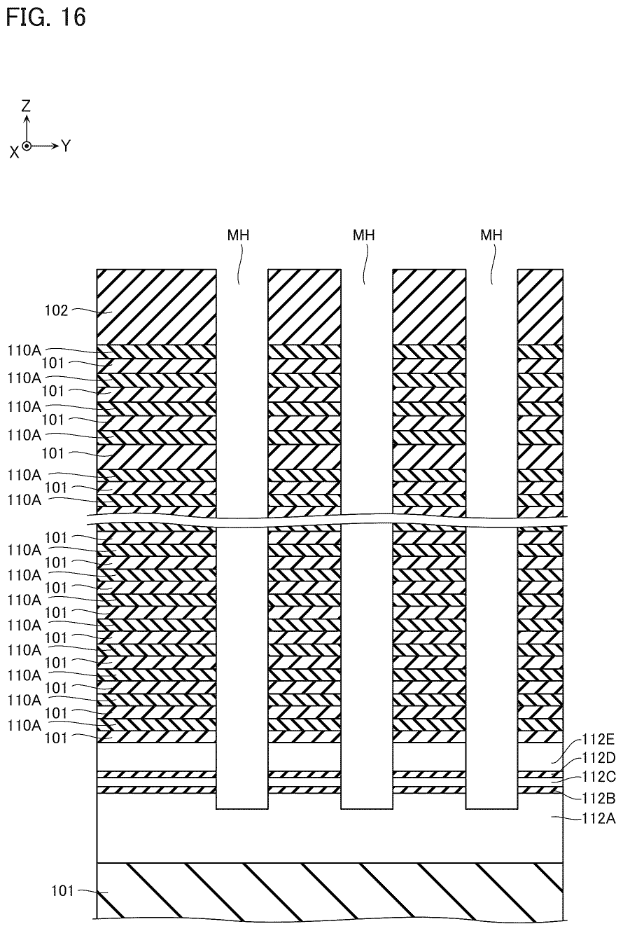

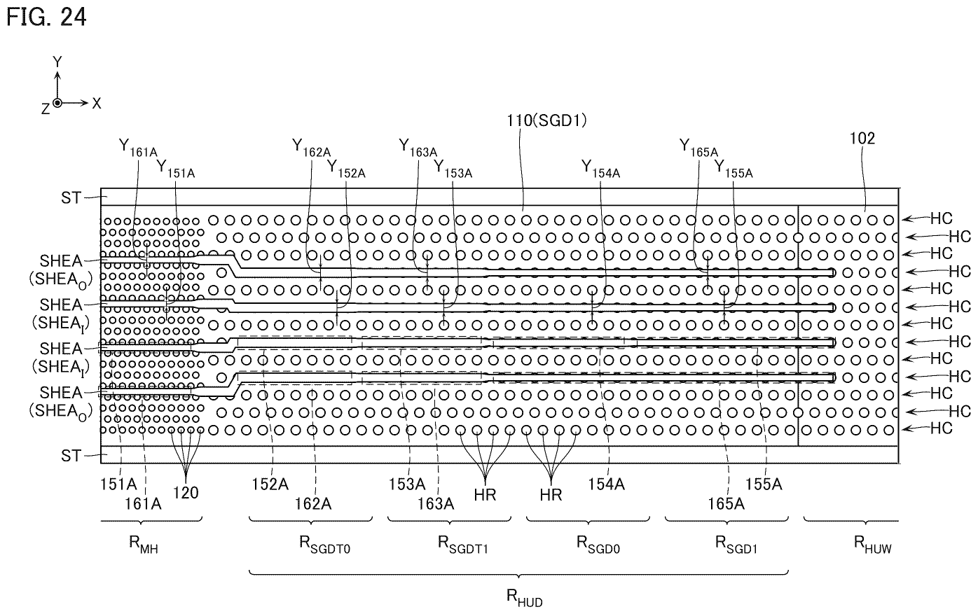

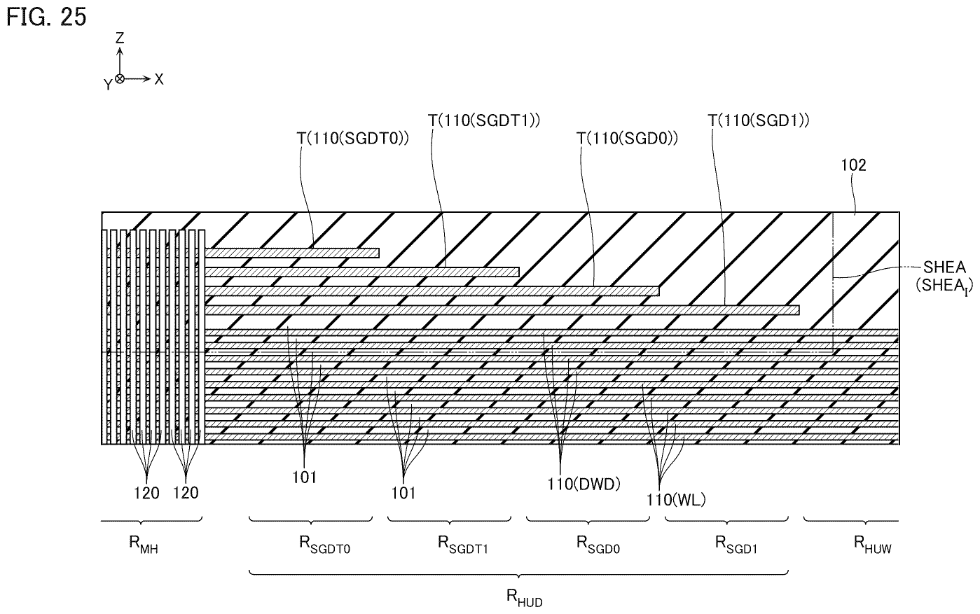

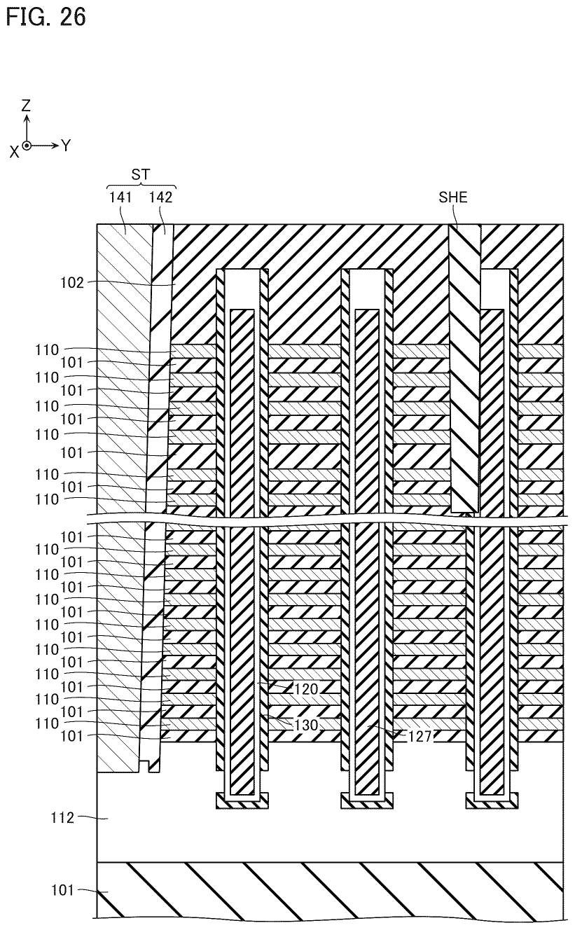

Next, with reference to FIG. 12 to FIG. 26, a method for manufacturing the semiconductor memory device according to the first embodiment is described. FIG. 12, FIG. 14, FIG. 16 to FIG. 23, and FIG. 26 are schematic cross-sectional views for describing the manufacturing method, and illustrate cross-sectional surfaces corresponding to FIG. 5. FIG. 13, FIG. 15, and FIG. 25 are schematic cross-sectional views for describing the manufacturing method, and illustrate cross-sectional surfaces corresponding to FIG. 10. FIG. 24 is a schematic plan view for describing the manufacturing method, and illustrates a cross-sectional surface corresponding to FIG. 8.

In manufacturing the semiconductor memory device according to this embodiment, as illustrated in FIG. 12, for example, the insulating layer 101 is formed above a semiconductor substrate (not illustrated in FIG. 12). Next, a semiconductor layer 112A of silicon or the like, a sacrifice layer 112B of silicon oxide or the like, a sacrifice layer 112C of silicon or the like, a sacrifice layer 112D of silicon oxide or the like, and a semiconductor layer 112E of silicon or the like are formed on the insulating layer 101. Also, the plurality of insulating layers 101 and a plurality of sacrifice layers 110A are alternately formed. The sacrifice layers 110A contain, for example, silicon nitride (SiN). This process is performed by a method, such as Chemical Vapor Deposition (CVD).

Next, for example, as illustrated in FIG. 13, the plurality of insulating layers 101 and the plurality of sacrifice layers 110A are partially removed in the hook-up regions R_{HUD}, R_{HUW} to form a plurality of terrace portions TA. The terrace portion TA is, for example, a portion of an upper surface of the sacrifice layer 110A that does not overlap with other sacrifice layers 110A viewing from above. In this process, for example, a resist is formed above the uppermost sacrifice layer 110A. Further, removal of the sacrifice layers 110A, removal of the insulating layers 101, and the removal of a part of the resist are repeatedly performed. Note that the removal of the resist is performed by isotropic etching, such as wet etching.

Next, for example, as illustrated in FIG. 14 and FIG. 15, a part of the insulating layer 102 is formed. For example, this process is performed by a method, such as CVD.

Next, for example, as illustrated in FIG. 16, memory holes MH are formed at positions corresponding to the semiconductor columns 120. The memory holes MH extend in the Z-direction, penetrate the insulating layer 102, the insulating layers 101, the sacrifice layers 110A, the semiconductor layer 112E, the sacrifice layer 112D, the sacrifice layer 112C, and the sacrifice layer 112B, and expose an upper surface of the semiconductor layer 112A. For example, this process is performed by a method, such as Reactive Ion Etching (RIE). Although not illustrated, via holes may be formed at positions corresponding to the support insulating columns HR in this process.

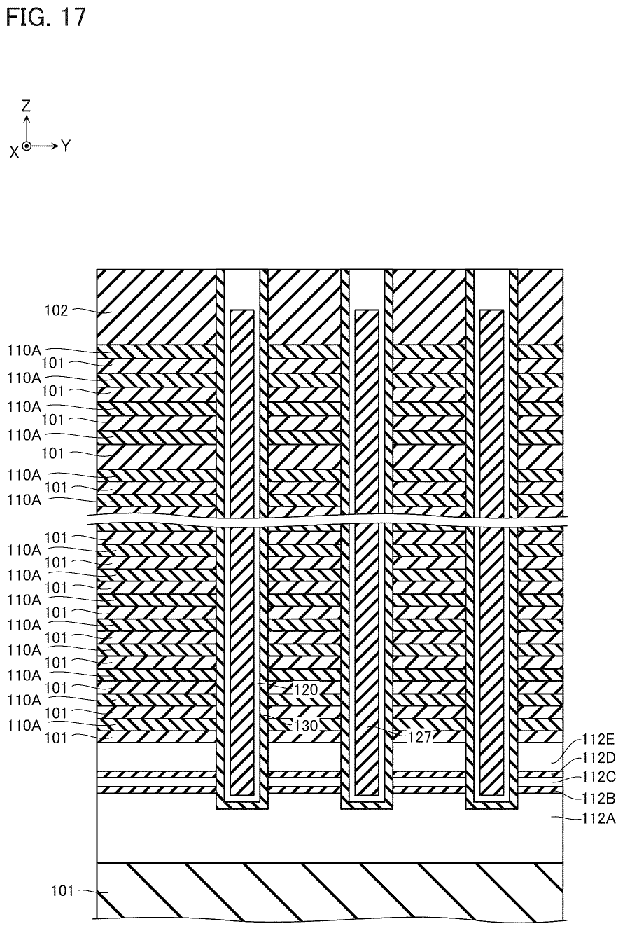

Next, for example, as illustrated in FIG. 17, the gate insulating films 130, the semiconductor columns 120, and the insulating columns 127 are formed inside the memory holes MH. For example, this process is performed by a method, such as CVD. Although not illustrated, the support insulating columns HR may be formed in this process.

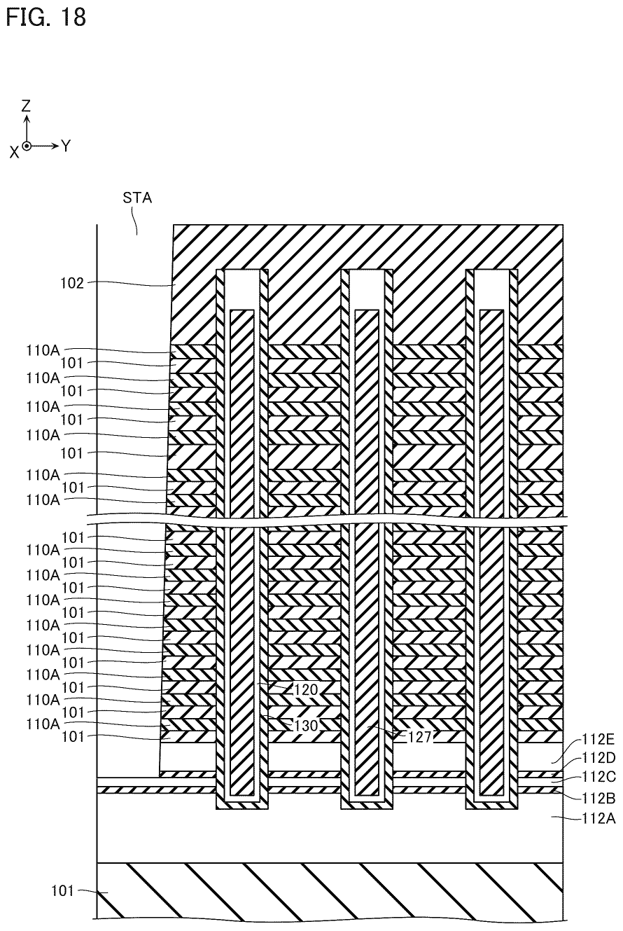

Next, for example, as illustrated in FIG. 18, a part of the insulating layer 102 is formed by a method, such as CVD. Further, a trench STA is formed at a position corresponding to the inter-finger structure ST. The trench STA extends in the Z-direction and the X-direction, separates the insulating layer 102, the plurality of insulating layers 101, the plurality of sacrifice layers 110A, the semiconductor layer 112E, and the sacrifice layer 112D in the Y-direction, and exposes the sacrifice layer 112C. For example, this process is performed by a method, such as RIE.

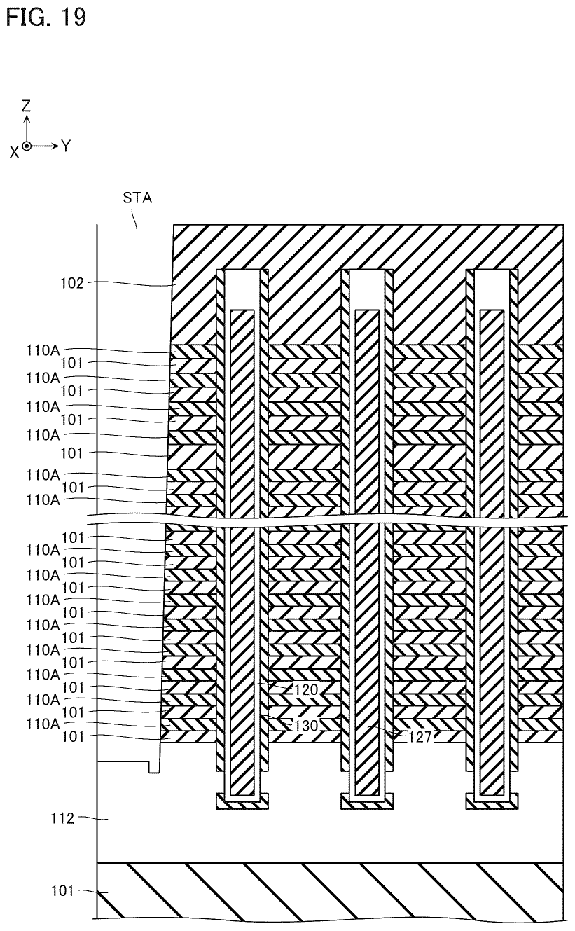

Next, for example, as illustrated in FIG. 19, the sacrifice layer 112B, the sacrifice layer 112C, the sacrifice layer 112D, and a part of the gate insulating film 130 are removed to form the conductive layer 112. For example, the removal of the sacrifice layer 112B, the sacrifice layer 112C, the sacrifice layer 112D, and the part of the gate insulating film 130 is performed by a method, such as wet etching. For example, the formation of the conductive layer 112 is performed by a method, such as epitaxial growth.

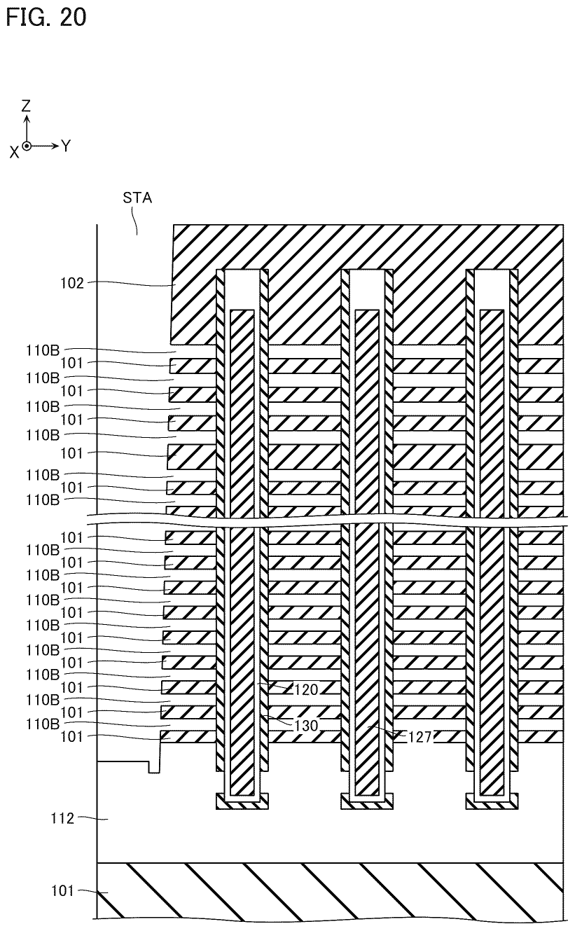

Next, for example, as illustrated in FIG. 20, the sacrifice layers 110A are removed via the trench STA to form a plurality of cavities 110B. Accordingly, a hollow structure including the plurality of insulating layers 101 and the insulating layer 102 that are arranged in the Z-direction, and structures in the memory holes MH (the semiconductor columns 120, the gate insulating films 130, and the insulating columns 127) and the support insulating columns HR supporting the plurality of insulating layers 101 and the insulating layer 102 are formed. For example, this process is performed by a method, such as wet etching.

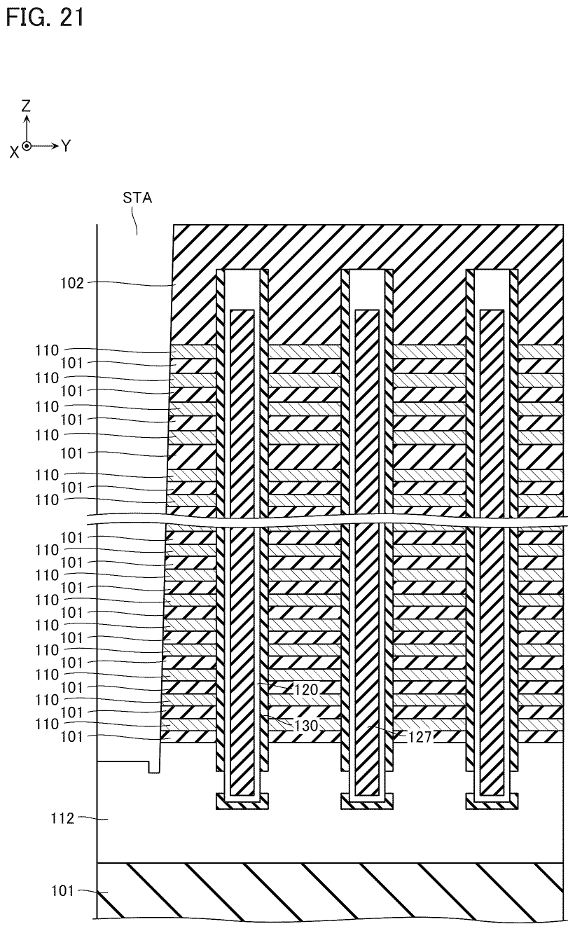

Next, for example, as illustrated in FIG. 21, the conductive layers 110 are formed at the cavities 110B. For example, this process is performed by a method, such as CVD using tungsten hexafluoride (WF₆).

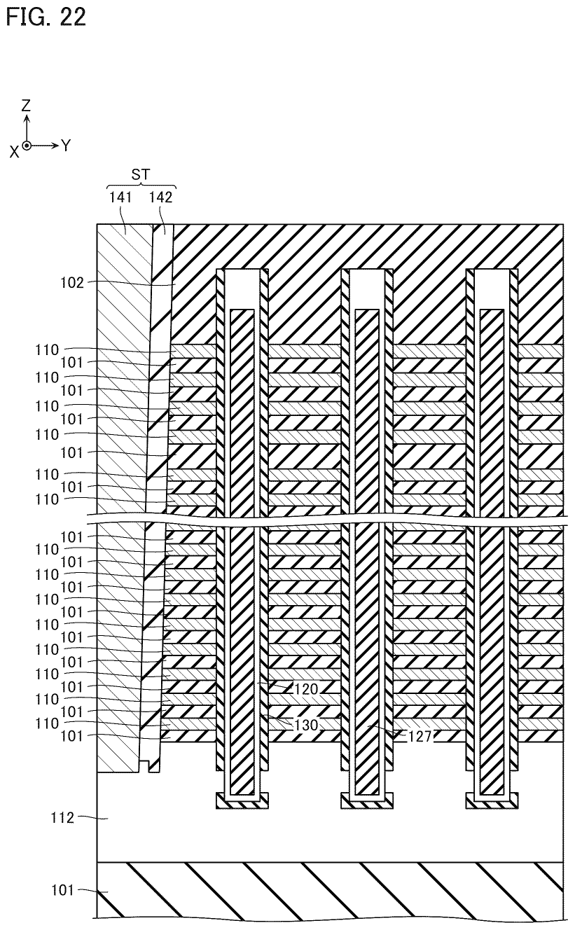

Next, for example, as illustrated in FIG. 22, the inter-finger structure ST is formed in the trench STA. For example, this process is performed by a method, such as CVD and RIE.

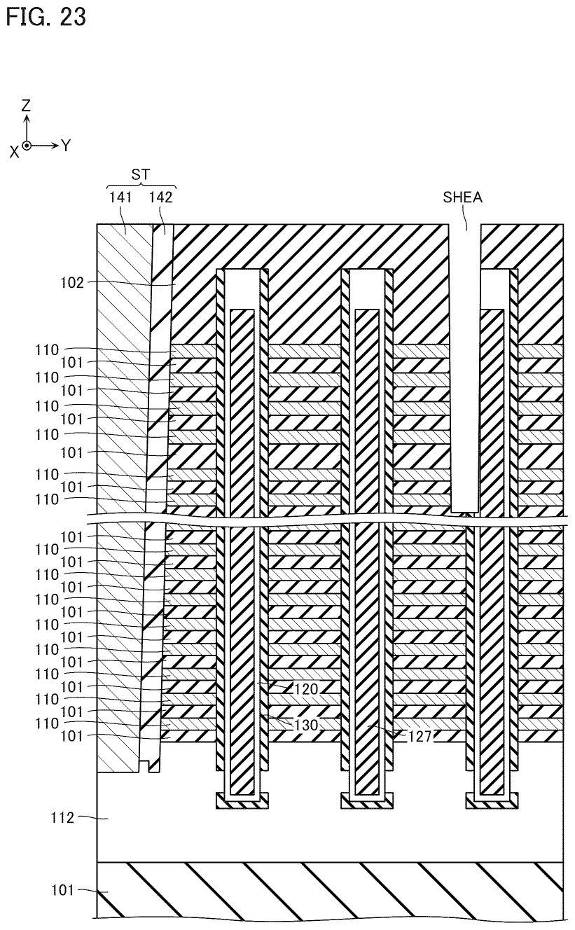

Next, for example, as illustrated in FIG. 23 to FIG. 25, a trench SHEA is formed at a position corresponding to the inter-string unit insulating member SHE. The trench SHEA extends in the Z-direction and the X-direction, and separates the insulating layer 102, the conductive layers 110 (SGDT0), 110 (SGDT1), 110 (SGD0), 110 (SGD1), a part of the conductive layers 110 (DWD), and the insulating layers 101 disposed on upper surfaces and lower surfaces in the Y-direction of these conductive layers 110. For example, this process is performed by a method, such as RIE. After this process is performed, for example, wet etching or the like of residue treatment may be performed.

The trench SHEA has a shape corresponding to the inter-string unit insulating member SHE.

That is, as illustrated in FIG. 24, a trench SHEA_{I} corresponding to the inter-string unit insulating member SHE_{I} includes a trench portion 151A provided in the semiconductor column region R_{MH}, a trench portion 152A provided in the terrace region R_{SGDT0}, a trench portion 153A provided in the terrace region R_{SGDT1}, a trench portion 154A provided in the terrace region R_{SGD0}, and a trench portion 155A provided in the terrace region R_{SGD1}. Each of the trench portions 151A, 152A, 153A, 154A, 155A has an approximately constant width in the Y-direction and extends in the X-direction. In the example of the drawing, center positions in the Y-direction of the trench portions 152A, 153A, 154A, 155A are approximately matched. Meanwhile, a center position in the Y-direction of the trench portion 151A is different from the center positions in the Y-direction of the trench portions 152A, 153A, 154A, 155A. The trench portion 152A has one end portion and the other end portion in the X-direction provided in the terrace region R_{SGDT0}. The trench portion 153A has one end portion in the X-direction provided in the terrace region R_{SGDT0}, and the other end portion in the X-direction provided in the terrace region R_{SGDT1}. The trench portion 154A has one end portion in the X-direction provided in the terrace region R_{SGDT1}, and the other end portion in the X-direction provided in the terrace region R_{SGD0}. The trench portion 155A has one end portion in the X-direction provided in the terrace region R_{SGD0}, and the other end portion in the X-direction provided in the hook-up region R_{HUW}.

Further, a trench SHEAₒ corresponding to the inter-string unit insulating member SHEₒ includes a trench portion 161A provided in the semiconductor column region R_{MH}, a trench portion 162A provided in the terrace region R_{SGDT0}, a trench portion 163A provided in the terrace region R_{SGDT1}, and a trench portion 165A provided in the terrace regions R_{SGD0}, R_{SGD1}. Each of the trench portions 161A, 162A, 163A, 165A has an approximately constant width in the Y-direction and extends in the X-direction. In the example of the drawing, center positions in the Y-direction of the trench portions 162A, 163A, 165A are approximately matched. Meanwhile, a center position in the Y-direction of the trench portion 161A is different from the center positions in the Y-direction of the trench portions 162A, 163A, 165A. The trench portion 162A has one end portion and the other end portion in the X-direction provided in the terrace region R_{SGDT0}. The trench portion 163A has one end portion in the X-direction provided in the terrace region R_{SGDT0}, and the other end portion in the X-direction provided in the terrace region R_{SGDT1}.

The trench portion 165A has one end portion in the X-direction provided in the terrace region R_{SGDT1}, and the other end portion in the X-direction provided in the hook-up region R_{HUW}.

Here, widths Y_{151A}, Y_{161A} in the Y-direction of the trench portions 151A, 161A at a height position corresponding to the conductive layer 110 (SGD1) are approximately matched. Widths Y_{152A}, Y_{162A} in the Y-direction of the trench portions 152A, 162A at the above-described height position are approximately matched. The widths Y_{152A}, Y_{162A} are larger than the widths Y_{151A}, Y_{161A}. A width Y_{153A} in the Y-direction of the trench portion 153A at the above-described height position is larger than a width Y_{163A} in the Y-direction of the trench portion 163A at the above-described height position. The widths Y_{153A}, Y_{163A} are larger than the widths Y_{151A}, Y_{161A}, and smaller than the widths Y_{152A}, Y_{162A}. A width Y_{154A} in the Y-direction of the trench portion 154A at the above-described height position is larger than the widths Y_{151A}, Y_{161A}, and smaller than the widths Y_{153A}, Y_{163A}. Widths Y_{155A}, Y_{165A} in the Y-direction of the trench portions 155A, 165A at the above-described height position are approximately matched with the widths Y_{151A}, Y_{161A}.

Next, for example, as illustrated in FIG. 26, the inter-string unit insulating member SHE is formed in the trench SHEA. For example, this process is performed by forming an insulating member of silicon oxide or the like inside the trench SHEA and on an upper surface of the insulating layer 102 by a method, such as CVD, and removing the insulating member formed on the upper surface of the insulating layer 102 by a method, such as RIE. Therefore, the inter-string unit insulating member SHE has a shape along the trench SHEA.

Subsequently, by forming the via-contact electrodes CC, Ch, Vy, the bit lines BL, and the like, the structure as described with reference to FIG. 3 to FIG. 11 is formed.

### Effects

In the process described with reference to FIG. 23 to FIG. 25, as described above, the trench SHEA corresponding to the inter-string unit insulating member SHE is formed.

Here, in this process, the conductive layers 110 (SGDT0), 110 (SGDT1), 110 (SGD0), 110 (SGD1) are separated in the Y-direction. Therefore, the processing of the trench SHEA is controlled such that the lower end of the trench SHEA is located below the lower surface of the conductive layer 110 (SGD1) over the whole semiconductor column region R_{MH} and hook-up region R_{HUD}.

On the other hand, when the lower end of the trench SHEA reaches below the lower surface of the uppermost conductive layer 110 (WL), in the wet etching of residue treatment at the formation of the trench SHEA, fluorine (F) contained in the conductive layer 110 (WL) is degassed, and this possibly deteriorates a film quality of the insulating layers 101 disposed on the upper and lower sides of the conductive layers 110 (WL). Here, at a write operation and the like, a comparatively large voltage difference is generated between two conductive layers 110 (WL) adjacent in the Z-direction. Therefore, deterioration of the film quality of the insulating layer 101 between the conductive layers 110 (WL) cause a concern about occurrence of leakage current or short circuit. Accordingly, it is preferred that the lower end of the trench SHEA is controlled to be located above the lower surface of the uppermost conductive layer 110 (WL) over the whole semiconductor column region R_{MH} and hook-up region R_{HUD}.

However, provisionally, for example, when the width in the Y-direction of the trench SHEA is uniform over the whole hook-up region R_{HUD}, there is a concern that a part of the lower end of the trench SHEA is located above the lower surface of the conductive layer 110 (SGD1), preventing the conductive layer 110 (SGD1) from being separated in the Y-direction, and a concern that a part of the lower end of the trench SHEA is located below the lower surface of the uppermost conductive layer 110 (WL), causing the leakage current or short circuit.

For example, in the process described with reference to FIG. 23 to FIG. 25, RIE is performed under a condition in which it is difficult to perform etching of metal, such as tungsten compared with silicon oxide or the like.

Here, in the example of FIG. 25, the trench SHEA separates mainly six conductive layers 110 in the semiconductor column region R_{MH} and terrace region R_{SGDT0}, separates mainly five conductive layers 110 in the terrace region R_{SGDT1}, separates mainly four conductive layers 110 in the terrace region R_{SGD0}, and separate mainly three conductive layers 110 in the terrace region R_{SGD1}. In the example of FIG. 25, the end portion of the trench SHEA is positioned in the hook-up region R_{HUW}, and this end portion cuts off two conductive layers 110. Therefore, provisionally, when the cutting of the conductive layer 110 that limits the progress of the etching here progresses over the whole hook-up region R_{HUD} at an approximately uniform speed, for example, at a time point at which five conductive layers 110 are cut in the terrace region R_{SGDT0}, the end portion of the trench SHEA cuts off the five conductive layers 110 also in the hook-up region R_{HUW}, and as described above, the leakage current or the short circuit is caused in some cases.

Accordingly, in this embodiment, in the trench SHEA_{I}, the width Y_{155A} of the trench portion 155A is formed to be smaller than the width Y_{154A} of the trench portion 154A, the width Y_{154A} of the trench portion 154A is formed to be smaller than the width Y_{153A} of the trench portion 153A, the width Y_{153A} of the trench portion 153A is formed to be smaller than the width Y_{152A} of the trench portion 152A. Further, in the trench SHEAₒ, the width Y_{165A} of the trench portion 165A is formed to be smaller than the width Y_{163A} of the trench portion 163A, and the width Y_{163A} of the trench portion 163A is formed to be smaller than the width Y_{162A} of the trench portion 162A.

Generally, when trench portions mutually different in width are to be simultaneously formed by etching, the larger the width of the trench portion is, the more the etching rate of RIE or the like increases. On the other hand, the smaller the width of the trench portion is, the more the etching rate of RIE or the like decreases. Therefore, according to the method of this embodiment, the etching rate of RIE or the like is adjusted to suppress a variation of the height of the lower end of the trench SHEA in the terrace regions R_{SGDT0}, R_{SGDT1}, R_{SGD0}, R_{SGD1}, and this allows the height position of the lower end of the trench SHEA to fall within a desired range.

In this embodiment, a plurality of semiconductor columns 120 and the like are formed in the semiconductor column region R_{MH}, and a plurality of support insulating columns HR are formed in the hook-up region R_{HUD}. Here, a density of the semiconductor column 120 and the like in the semiconductor column region R_{MH} is larger than a density of the support insulating column HR in the hook-up region R_{HUD}. On the other hand, a density of the conductive layer 110 in the semiconductor column region R_{MH} is smaller than a density of the conductive layer 110 in the hook-up region R_{HUD}. Therefore, provisionally, for example, when the width in the Y-direction of the trench SHEA is uniform over the whole semiconductor column region R_{MH} and hook-up region R_{HUD}, the height of the lower end of the trench SHEA is possibly located below the lower surface of the uppermost conductive layer 110 (WL) in the semiconductor column region R_{MH}.

Accordingly, in this embodiment, the width Y_{151A} of the trench portion 151A is formed to be smaller than the width Y_{152A} of the trench portion 152A. Similarly, the width Y_{161A} of the trench portion 161A is formed to be smaller than the width Y_{162A} of the trench portion 162A. Therefore, according to the method of this embodiment, the etching rate of RIE or the like is adjusted to suppress a difference between the height of the lower end of the trench SHEA in the semiconductor column region R_{MH} and the height of the lower end of the trench SHEA in the hook-up region R_{HUD}, and this allows the height position of the lower end of the trench SHEA to fall within a desired range.

Further, when the widths in the Y-direction of the trench SHEA_{I} and the widths in the Y-direction of the trench SHEAₒ in the terrace regions R_{SGDT0}, R_{SGDT1}, R_{SGD0}, R_{SGD1} are all matched, in the process described with reference to FIG. 23 to FIG. 25, a part of the trench SHEAₒ is formed to be deeper than the trench SHEA_{I} in some cases.

Therefore, in this embodiment, the width Y_{163A} of the trench portion 163A is formed to be smaller than the width Y_{153A} of the trench portion 153A in the terrace region R_{SGDT1}. The width Y_{165A} of the trench portion 165A is formed to be smaller than the width Y_{154A} of the trench portion 154A in the terrace region R_{SGD0}. Accordingly, the etching rate of RIE or the like is adjusted to suppress a variation between the heights of the lower ends of the trenches SHEA_{I}, SHEAₒ, and this allows the height positions of the lower ends of the trenches SHEA_{I}, SHEAₒ to fall within a desired range.

### Second Embodiment

In the first embodiment, the width in the Y-direction of the trench SHEA_{I} is adjusted in four levels in the hook-up region R_{HUD} corresponding to the number of the conductive layers 110 to be cut. The width in the Y-direction of the trench SHEAₒ is adjusted in three levels in the hook-up region R_{HUD}. However, such a configuration is only an example, and the number of levels in which the widths in the Y-direction of the trenches SHEA_{I}, SHEAₒ in the hook-up region R_{HUD} vary can be appropriately adjusted.

That is, even by adjusting the width in the Y-direction of the trench SHEA in only two levels in the hook-up region R_{HUD}, the variation of the height of the lower end of the trench SHEA can be suppressed compared with a case in which the width in the Y-direction of the trench SHEA is uniform. For example, when a difference between the etching rate of silicon oxide or the like and the etching rate of metal, such as tungsten is small in the process described with reference to FIG. 23 to FIG. 25, it may be possible to sufficiently suppress the variation of the height of the lower end of the trench SHEA by such an adjustment in two levels.

For example, to suppress that the conductive layers 110 more than expected are cut by the end portion of the trench SHEA in the hook-up region R_{HUW}, the width in the Y-direction of the trench SHEA may be adjusted in the levels with one more level at the proximity of the end portion of the conductive layer 110 (SGD1).

An example in which the widths in the Y-direction of the trenches SHEA_{I}, SHEAₒ are adjusted in two levels in the hook-up region R_{HUD} as a semiconductor memory device according to the second embodiment is described below.

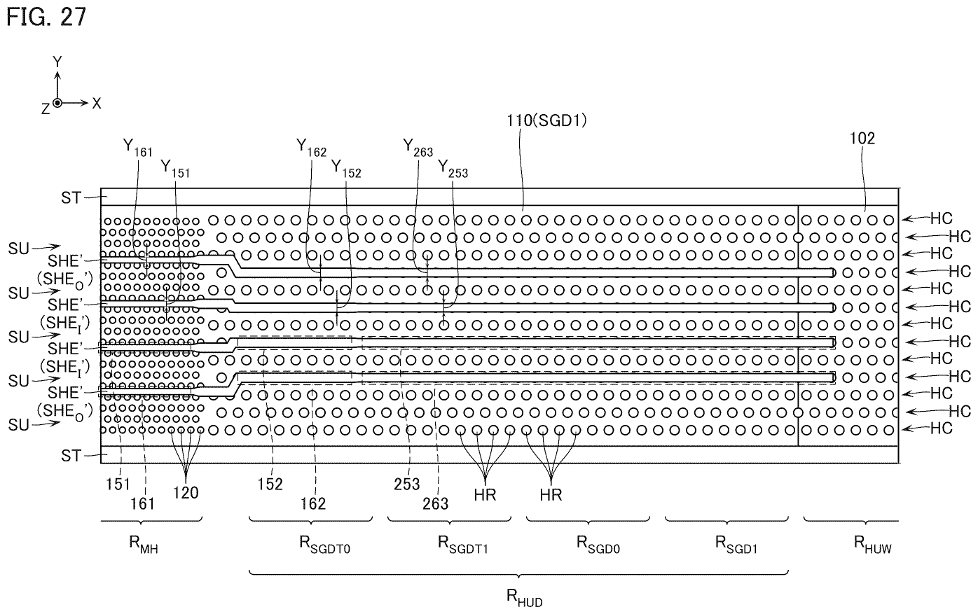

FIG. 27 is a schematic plan view of the semiconductor memory device according to the second embodiment. FIG. 27 illustrates an XY cross-sectional surface at a height position corresponding to the conductive layer 110 (SGD1).

The semiconductor memory device according to the second embodiment is basically configured similarly to the semiconductor memory device according to the first embodiment. However, the semiconductor memory device according to the second embodiment includes an inter-string unit insulating member SHE′ instead of the inter-string unit insulating member SHE.

In the following description, first and fourth inter-string unit insulating members SHE′ counted from the Y-direction positive side are referred to as an inter-string unit insulating member SHEₒ′ in some cases. Second and third inter-string unit insulating members SHE′ counted from the Y-direction positive side are referred to as an inter-string unit insulating member SHE_{I}′ in some cases.

The inter-string unit insulating member SHE_{I}′ according to the embodiment is basically configured similarly to the inter-string unit insulating member SHE_{I}. However, the inter-string unit insulating member SHE_{I}′ includes an insulating portion 253 provided in the terrace regions R_{SGDT1}, R_{SGD0}, R_{SGD1} instead of the insulating portions 153, 154, 155. The insulating portion 253 has an approximately constant width in the Y-direction and extends in the X-direction. In the example of the drawing, a center position in the Y-direction of the insulating portion 253 is approximately matched with the center position in the Y-direction of the insulating portion 152. The insulating portion 253 has one end portion in the X-direction provided in the terrace region R_{SGDT0}, and the other end portion in the X-direction provided in the hook-up region R_{HUW}.

The inter-string unit insulating member SHEₒ′ according to the embodiment is basically configured similarly to the inter-string unit insulating member SHEₒ. However, the inter-string unit insulating member SHEₒ′ includes an insulating portion 263 provided in the terrace regions R_{SGDT1}, R_{SGD0}, R_{SGD1} instead of the insulating portions 163, 165. The insulating portion 263 has an approximately constant width in the Y-direction and extends in the X-direction. In the example of the drawing, a center position in the Y-direction of the insulating portion 263 is approximately matched with the center position in the Y-direction of the insulating portion 162. The insulating portion 263 has one end portion in the X-direction provided in the terrace region R_{SGDT0}, and the other end portion in the X-direction provided in the hook-up region R_{H}UW.

Here, a width Y₂₅₃ in the Y-direction of the insulating portion 253 at a height position corresponding to the conductive layer 110 (SGD1) is larger than a width Y₂₆₃ in the Y-direction of the insulating portion 263 at the above-described height position. The widths Y₂₅₃, Y₂₆₃ are larger than the widths Y₁₅₁, Y₁₆₁, and smaller than the widths Y₁₅₂, Y₁₆₂.

### Third Embodiment

In the first embodiment, the width Y₁₆₃ in the Y-direction of the insulating portion 163 provided in the terrace region R_{SGDT1} is smaller than the width Y₁₅₃ in the Y-direction of the insulating portion 153. The width Y₁₆₅ in the Y-direction of the insulating portion 165 provided in the terrace region R_{SGD0} is smaller than the width Y₁₅₄ in the Y-direction of the insulating portion 154. However, such a configuration is only an example, and the widths in the terrace regions R_{SGDT0}, R_{SGDT1}, R_{SGD0}, R_{SGD1} of the inter-string unit insulating member SHEₒ may be approximately matched with the widths in the terrace regions R_{SGDT0}, R_{SGDT1}, R_{SGD0}, R_{SGD1} of the inter-string unit insulating member SHE_{I}, respectively.

An example in which the widths in the Y-direction of the inter-string unit insulating members SHE_{I}, SHEₒ are approximately matched in each region as a semiconductor memory device according to the third embodiment is described below.

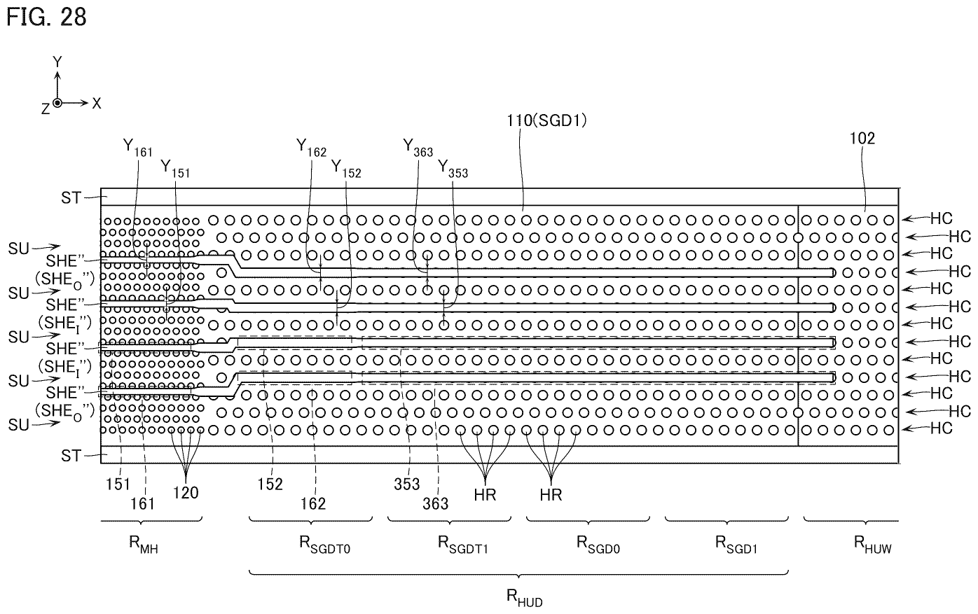

FIG. 28 is a schematic plan view of the semiconductor memory device according to the third embodiment. FIG. 28 illustrates an XY cross-sectional surface at a height position corresponding to the conductive layer 110 (SGD1).

The semiconductor memory device according to the third embodiment is basically configured similarly to the semiconductor memory device according to the second embodiment. However, the semiconductor memory device according to the third embodiment includes an inter-string unit insulating member SHE″ instead of the inter-string unit insulating member SHE′.

In the following description, first and fourth inter-string unit insulating members SHE″ counted from the Y-direction positive side are referred to as an inter-string unit insulating member SHEₒ″ in some cases. Second and third inter-string unit insulating members SHE″ counted from the Y-direction positive side are referred to as an inter-string unit insulating member SHE_{I}″ in some cases.

The inter-string unit insulating member SHE_{I}″ according to the embodiment is basically configured similarly to the inter-string unit insulating member SHE_{I}′. However, the inter-string unit insulating member SHE_{I}″ includes an insulating portion 353 instead of the insulating portion 253. The insulating portion 353 is basically configured similarly to the insulating portion 253.

The inter-string unit insulating member SHEₒ″ according to the embodiment is basically configured similarly to the inter-string unit insulating member SHEₒ′. However, the inter-string unit insulating member SHEₒ″ includes an insulating portion 363 instead of the insulating portion 263. The insulating portion 363 is basically configured similarly to the insulating portion 263.

Here, a width Y₃₅₃ in the Y-direction of the insulating portion 353 at a height position corresponding to the conductive layer 110 (SGD1) is approximately matched with a width Y₃₆₃ in the Y-direction of the insulating portion 363 at the above-described height position. The widths Y₃₅₃, Y₃₆₃ are larger than the widths Y₁₅₁, Y₁₆₁, and smaller than the widths Y₁₅₂, Y₁₆₂.

### Other Embodiments

The semiconductor memory devices according to the first embodiment to the third embodiment are described above. However, the above descriptions are merely examples, and the specific configuration and the like are adjustable as appropriate.

For example, in the semiconductor memory devices according to the first embodiment to the third embodiment, the widths in the Y-direction of the insulating portions 151, 152, 153, 154, 155, 161, 162, 163, 165, 253, 263, 353, 363 can be adjusted as appropriate. For example, in the first embodiment to the third embodiment, the widths Y₁₅₂, Y₁₆₂ in the Y-direction of the insulating portions 152, 162 at the height position corresponding to the conductive layer 110 (SGD1) are approximately matched. However, the width Y₁₆₂ may be smaller than the width Y₁₅₂.

For example, in the semiconductor memory devices according to the first embodiment to the third embodiment, the configuration that achieves the memory cell array MCA may be formed upside down. Accordingly, the conductive layers 110 (SGDT0), 110 (SGDT1), 110 (SGD0), 110 (SGD1) may be disposed below the conductive layers 110 (WL).

In the semiconductor memory devices according to the first embodiment to the third embodiment, the memory cell array region R_{MCA} includes the two semiconductor column regions R_{MH} arranged in the X-direction, the two hook-up regions R_{HUD} arranged in the X-direction between the two semiconductor column regions R_{MH}, and the hook-up region R_{HU}w disposed between the two hook-up regions R_{HUD}. However, such a configuration is merely an example, and the arrangement of the semiconductor column region R_{MH}, the hook-up region R_{HUD}, and the hook-up region R_{HUW} can be adjusted as appropriate. For example, the hook-up regions R_{HUD}, R_{HUW} may be disposed at one end or both ends of the memory cell array region R_{MCA} in the X-direction. For example, the hook-up region R_{HUD} may be disposed between the single semiconductor column region R_{MH} and the hook-up region R_{HUW}.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of conductive layers stacked in a stacking direction and including a plurality of first conductive layers extending in a first direction intersecting with the stacking direction over a semiconductor column region, a first terrace region, and a second terrace region arranged in the first direction, a second conductive layer extending in the first direction over the semiconductor column region and the first terrace region and including a terrace portion provided in the first terrace region, and a third conductive layer disposed between the plurality of first conductive layers and the second conductive layer, extending in the first direction over the semiconductor column region, the first terrace region, and the second terrace region, and including a terrace portion provided in the second terrace region;
a semiconductor column disposed in the semiconductor column region, extending in the stacking direction, and opposed to the plurality of conductive layers;
a gate insulating film disposed between the plurality of conductive layers and the semiconductor column and including an electric charge accumulating film; and
a first insulating member extending in the stacking direction in a range corresponding to a part of the plurality of conductive layers including the second conductive layer and the third conductive layer in the stacking direction, the first insulating member including a first insulating portion extending in the first direction in the first terrace region and a second insulating portion extending in the first direction in the second terrace region, wherein
the second insulating portion has a width in a second direction intersecting with the stacking direction and the first direction at a first position in the stacking direction smaller than a width in the second direction of the first insulating portion at the first position in the stacking direction.

2. The semiconductor memory device according to claim 1, wherein
at the first position in the stacking direction:
the width in the second direction of the first insulating portion is approximately constant; and
the width in the second direction of the second insulating portion is approximately constant.

3. The semiconductor memory device according to claim 1, wherein
an end portion at an opposite side of the semiconductor column region in the first direction of the first insulating portion and an end portion at a semiconductor column region side in the first direction of the second insulating portion are provided in the first terrace region.

4. The semiconductor memory device according to claim 1, wherein
the plurality of first conductive layers further extend in the first direction in a third terrace region arranged with the second terrace region in the first direction and provided between the second terrace region and a plurality of fourth terrace regions in which a plurality of terrace portions of the plurality of first conductive layers are provided,
the plurality of conductive layers further include a fourth conductive layer disposed between the plurality of first conductive layers and the third conductive layer, the fourth conductive layer extends in the first direction over the semiconductor column region, the first terrace region, the second terrace region, and the third terrace region, and includes a terrace portion provided in the third terrace region,
the part of the plurality of conductive layers further includes the fourth conductive layer,
the first insulating member further includes a third insulating portion extending in the first direction in the third terrace region, and
the third insulating portion has a width in the second direction at the first position in the stacking direction smaller than the width in the second direction of the second insulating portion at the first position in the stacking direction.

5. The semiconductor memory device according to claim 4, wherein
at the first position in the stacking direction:
the width in the second direction of the first insulating portion is approximately constant;
the width in the second direction of the second insulating portion is approximately constant; and
the width in the second direction of the third insulating portion is approximately constant.

6. The semiconductor memory device according to claim 4, wherein
an end portion at an opposite side of the semiconductor column region in the first direction of the first insulating portion and an end portion at a semiconductor column region side in the first direction of the second insulating portion are provided in the first terrace region, and
an end portion at the opposite side of the semiconductor column region in the first direction of the second insulating portion and an end portion at the semiconductor column region side in the first direction of the third insulating portion are provided in the second terrace region.

7. The semiconductor memory device according to claim 1, wherein
the plurality of first conductive layers further extend in the first direction in a third terrace region arranged with the second terrace region in the first direction and provided between the second terrace region and a plurality of fourth terrace regions in which a plurality of terrace portions of the plurality of first conductive layers are provided,
the plurality of conductive layers further include a fourth conductive layer disposed between the plurality of first conductive layers and the third conductive layer, the fourth conductive layer extends in the first direction over the semiconductor column region, the first terrace region, the second terrace region, and the third terrace region, and includes a terrace portion provided in the third terrace region,
the part of the plurality of conductive layers further includes the fourth conductive layer, and
the second insulating portion further extends in the first direction in the third terrace region.

8. The semiconductor memory device according to claim 1, wherein
one end portion in the stacking direction of the first insulating member is provided between a surface at a plurality of first conductive layers side in the stacking direction of the third conductive layer and a surface at an opposite side of the third conductive layer of a first conductive layer disposed at a most third conductive layer side among the plurality of first conductive layers.

9. The semiconductor memory device according to claim 1, wherein
a width in the second direction of the first insulating member at the first position in the stacking direction monotonously decreases, over the first terrace region and a region at an opposite side in the first direction of the semiconductor column region with respect to the first terrace region, from a first terrace region side toward the opposite side of the semiconductor column region.

10. The semiconductor memory device according to claim 1, wherein
the first insulating member further includes a fourth insulating portion extending in the first direction in the semiconductor column region, and
the fourth insulating portion has a width in the second direction at the first position in the stacking direction smaller than the width in the second direction of the first insulating portion at the first position in the stacking direction.

11. The semiconductor memory device according to claim 1, further comprising:
a second insulating member arranged with the first insulating member in the second direction, extending in the stacking direction in the range corresponding to the part of the plurality of conductive layers in the stacking direction, and extending in the first direction over the semiconductor column region, the first terrace region, and the second terrace region, wherein
at a second position in the first direction corresponding to the first terrace region or the second terrace region, the second insulating member has a width in the second direction at the first position in the stacking direction smaller than a width in the second direction of the first insulating member at the first position in the stacking direction.

12. The semiconductor memory device according to claim 11, wherein
the second insulating member includes:
a fifth insulating portion extending in the first direction in the first terrace region; and
a sixth insulating portion extending in the first direction in the second terrace region, and
the sixth insulating portion has a width in the second direction at the first position in the stacking direction smaller than a width in the second direction of the fifth insulating portion at the first position in the stacking direction.

13. The semiconductor memory device according to claim 12, wherein
at the first position in the stacking direction:
the width in the second direction of the first insulating portion is approximately constant;
the width in the second direction of the second insulating portion is approximately constant;
the width in the second direction of the fifth insulating portion is approximately constant; and
the width in the second direction of the sixth insulating portion is approximately constant.

14. The semiconductor memory device according to claim 12, wherein
the width in the second direction of the sixth insulating portion at the first position in the stacking direction is smaller than the width in the second direction of the second insulating portion at the first position in the stacking direction.

15. The semiconductor memory device according to claim 12, wherein
the width in the second direction of the fifth insulating portion at the first position in the stacking direction is approximately matched with the width in the second direction of the first insulating portion at the first position in the stacking direction.

16. The semiconductor memory device according to claim 11, wherein
one end portion in the stacking direction of the first insulating member and one end portion in the stacking direction of the second insulating member are provided between a surface at a plurality of first conductive layers side in the stacking direction of the third conductive layer and a surface at an opposite side of the third conductive layer of a first conductive layer disposed at a most third conductive layer side among the plurality of first conductive layers.

17. The semiconductor memory device according to claim 11, wherein
a width in the second direction of the first insulating member at the first position in the stacking direction and a width in the second direction of the second insulating member at the first position in the stacking direction monotonously decrease, over the first terrace region and a region at an opposite side in the first direction of the semiconductor column region with respect to the first terrace region, from a first terrace region side toward the opposite side of the semiconductor column region.

18. The semiconductor memory device according to claim 12, wherein
the first insulating member further includes a fourth insulating portion extending in the first direction in the semiconductor column region,
the fourth insulating portion has a width in the second direction at the first position in the stacking direction smaller than the width in the second direction of the first insulating portion at the first position in the stacking direction,
the second insulating member further includes a seventh insulating portion extending in the first direction in the semiconductor column region, and
the seventh insulating portion has a width in the second direction at the first position in the stacking direction smaller than the width in the second direction of the fifth insulating portion at the first position in the stacking direction.

19. A semiconductor memory device comprising:
a plurality of conductive layers stacked in a stacking direction and including a plurality of first conductive layers extending in a first direction intersecting with the stacking direction over a semiconductor column region and a first terrace region arranged in the first direction and a second conductive layer extending in the first direction over the semiconductor column region and the first terrace region and including a terrace portion provided in the first terrace region;
a semiconductor column disposed in the semiconductor column region, extending in the stacking direction, and opposed to the plurality of conductive layers;
a gate insulating film disposed between the plurality of conductive layers and the semiconductor column and including an electric charge accumulating film;
a first insulating member overlapped with the plurality of first conductive layers in the stacking direction, and extending in the first direction in the semiconductor column region and the first terrace region in a range corresponding to a part of the plurality of conductive layers including the second conductive layer in the stacking direction; and
a second insulating member arranged with the first insulating member in a second direction intersecting with the stacking direction and the first direction, overlapped with the plurality of first conductive layers in the stacking direction, and extending in the first direction in the semiconductor column region and the first terrace region in the range corresponding to the part of the plurality of conductive layers in the stacking direction, wherein
at a position in the first direction corresponding to the first terrace region, a width in the second direction of the second insulating member is smaller than a width in the second direction of the first insulating member.

20. The semiconductor memory device according to claim 19, wherein
the plurality of conductive layers further include a third conductive layer at an opposite side of the plurality of first conductive layers with respect to the second conductive layer in the stacking direction, and the third conductive layer includes a terrace portion provided in a second terrace region between the semiconductor column region and the first terrace region,
the first insulating member and the second insulating member further extend in the first direction in the second terrace region in a range corresponding to a part of the plurality of conductive layers including the second conductive layer and the third conductive layer in the stacking direction, and
at a position in the first direction corresponding to the second terrace region, a width in the second direction of the second insulating member is approximately matched with a width in the second direction of the first insulating member.
